(19) United States
(12) Patent Application Publication
(10) Pub. No.: US 2018/0206043 A1
(43) Pub. Date: Jul. 19, 2018

(54) AN ULTRA-LOW-POWER ULTRA-LOW-NOISE MICROPHONE

(71) Applicant: WIZEDSP LTD., TEL-AVIV (IL)

(72) Inventor: OZ GABAI, TEL-AVIV (IL)

(21) Appl. No.: 15/743,672

(22) PCT Filed: Jul. 11, 2016
(86) PCT No.: PCT/IB16/54136

§ 371 Date: Jan. 11, 2018

Related U.S. Application Data
(60) Provisional application No. 62/191,439, filed on Jul. 12, 2015.

(51) Int. Cl. H04R 19/04; H04R 19/01; H04R 19/00; H03F 1/56; H03F 3/185; H03F 3/45

(52) U.S. Cl. CPC H04R 19/04; H04R 19/01; H04R 19/005; H03F 1/56; H03F 2200/294; H03F 3/1855; H03F 3/45; H04R 2410/03; H03F 2200/03; H03F 3/185

(57) ABSTRACT

A microphone circuit including a JFET or MOSFET transistor, a terminal of an input-impedance-network connected to the transistor's gate, one terminal of a source resistor connected to the transistor's source, and another terminal connected to ground, a bypass capacitor connected in parallel to the source resistor, one terminal of a load resistor connected to the transistor's drain, a charge-pump generating low-voltage connected to the second terminal of the load resistor, and an inverted voltage connected to a power supply terminal of an op amplifier, one input of the op-amplifier connected to the source terminal of the transistor through a bi-directional low-pass-filter, another input connected to a reference voltage, one power supply terminal connected to the inverted voltage, another power supply terminal connected to main supply voltage, an output terminal connected to another terminal of the input-impedance-network through a low pass filter, where the input-impedance-network connected to a microphone.

### CROSS-REFERENCE TO RELATED APPLICATIONS

This application claims the benefit of U.S. Provisional Application No. 62/191,439, filed Jul. 12, 2015, the disclosure of which is incorporated herein by reference in its entirety.

### FIELD

The method and apparatus disclosed herein are related to the field of electronic circuitry, and, more particularly, but not exclusively to systems and methods providing ultra-low-power and an ultra-low-noise microphone buffer.

### BACKGROUND

Today, 2015, microphones are used nearly anywhere, in smartphones—where we have about 3 microphones for a smartphone, cellphones, Bluetooth earpieces, wired earpieces, toys, and billions of microphones sold every year.

Not only that, currently there are about 2 billion smartphones around the world. A smartphone is basically a cellphone with internet connection, palm computer and sensors. The smartphone keeps each one of us connected to the internet. Having applications stores like “Google Play” for Android phones and “App Store” for iOS based phones, each one of us can download applications in many categories such as Games, Navigation, etc. Smartphones are connected to the internet and have the ability to run applications that make our lives much more comfortable and easy.

In recent years, more and more devices are being connected to the internet, such as air conditioners, washing machines, TVs, electrical water boilers etc. There are many advantages of connecting a device to the internet, for example we can save money by connecting our electrical water boiler, washing machine and clothes dryer machine to the internet. We can save money because usually the electricity rates of depend on the hour, so usually in the morning time, residential electricity will cost less (as there is no much of electricity demand in the mornings). Therefore, we can set our Smart washing machine or clothes dryer machine in a save mode, and the machine will contact the server of the electricity utility company via the internet, and will receive rates as a function of time/day, and then activate the machine, only during low cost residential electricity time.

With respect to air conditioners, smart sensors, and smart homes, it is possible to have the “brain” of these machines running in internet servers, wherein neural network and artificial algorithms are used to activate them smartly. Having sensors installed in the house which report to this “brain” through the internet, can save us much time and money.

Not only that, it is now possible to have a battery based electricity generator that will charge the house battery when there is a low demand, and release power when demand and prices are high. In order for this technology to have the rate information, the battery based generator must be connected to the internet. That will allow it to connect to the electricity utility company server, and get the times/rates so to maximize the efficiency of the generator plan to save money.

In general, this is all called today by the name “Internet of Things” (IoT) or Internet of Everything (IoE).

Some of the benefits of connecting a device to the internet are: Ability to smart control the device—having the brain on the net or the ability to control each device from the palm of our hands, ability to observe and get information about the device, for a service like an off date usage, ability to locate devices, ability to provide better service by collecting and analyzing information received from the usage of each device like a tooth brush or a screw driver and the ability to get better price on products and services. Connecting devices to the internet can make our lives much more efficient.

The technology is rapidly advancing every day, and some have forecasted that by 2020, more than 50,000,000,000 devices would be connected to the internet, some of these devices will probably be: light bulbs, light switches, air conditions, tools such as screwdrivers, tooth brushes, medical devices such as potable blood pressure, books or toys.

It is clear that some IoT, or IoE devices that would be connected to the internet, would have a local power source. Such devices could be electrical water boilers and air conditioners. These IoT devices can use Wi-Fi, Bluetooth (BT), ZigBee or any other wireless standard or a Power line to connect the device to the home local router and hence to the internet. Some devices such as Glasses, Tools, clothes, Bath room moveable devices such as tooth brush, and toys would require batteries as an energy source. However, if the wireless communication is implemented using electromagnetic radio frequency communication, then power becomes a big issue. Such battery operated receivers, in order to keep battery life as long as possible, will periodically turn on for a short time, in order to check for incoming messages. Another option to operate a low power receiver, would incorporate a wake up receiver that basically detects a presence of energy in some band, and then checks if it is a valid marker. The two step process would usually save a lot of power, as the marker check is done only when a signal is detected. However, in the ISM band or in a radio frequency band, there is basically a lot of noise, and an implementation of selective band wakeup receiver is not an easy task when dealing with high bandwidth.

All these applications require extensive communication, which consumes power and drains the batteries of these devices too fast. There is thus a widely recognized need for, and it would be highly advantageous to have, a system and method providing a microphone buffer devoid of the above limitations.

### SUMMARY

According to one exemplary embodiment there is provided a device and a method for microphone including: a transistor such as a JFET transistor or a MOSFET transistor, an input-impedance-network including a first terminal connected to a gate terminal of the transistor, a first terminal of a source resistor connected to a source terminal of the transistor, and a second terminal connected to a ground terminal, a bypass capacitor connected in parallel to the source resistor, a load resistor including a first terminal connected to a drain terminal of the transistor, a charge-pump generating a low-voltage connected to the second terminal of the load resistor, and an inverted voltage connected to a first power supply node of an op amplifier, an op-amplifier including a first input terminal connected to the source terminal of the transistor through a bi-directional low-pass-filter, a second input terminal connected to a reference voltage, a first power supply terminal connected to the inverted voltage, a second power supply terminal connected to main supply voltage, and an output terminal connected to a second terminal of the input-impedance-network through a second low pass filter, and an electret capacitor connected in parallel to the input-impedance-network.

According to another exemplary embodiment there is provided a device and a method for microphone including: a transistor including at least one of a JFET transistor and a MOSFET transistor, an input-impedance-network including a first terminal connected to a gate of the transistor; a source resistor including a first terminal connected to a source terminal of the transistor, and a second terminal connected to a ground terminal, a bypass capacitor (CS) connected in parallel to the source resistor, a load resistor (RD) including a first terminal connected to a drain terminal of the transistor, a charge pump generating a low voltage power supply VCC_LOW connected to a second terminal of the load resistor, and an inverted voltage −VEE connected to a first power supply terminal of an op-amplifier, the op-amplifier including a first input terminal connected to the source terminal of the transistor through a bi-directional low-pass-filter, a second input terminal connected to a reference voltage Vref, a first power supply terminal connected to the inverted voltage, a second power supply terminal connected to main supply voltage, and an output terminal connected to a second terminal of the input-impedance-network through a second low pass filter, and an input source including a MEMS capacitor including a first terminal connected to ground, and a second terminal connected to a first terminal of a MEMS bias network, a MEMS bias network including a second terminal connected to a bias voltage (VBB), and a coupling capacitor including a first terminal connected to a second terminal of the MEMS capacitor, a second terminal connected to the gate terminal of the transistor.

According to yet another exemplary embodiment there is provided a device and a method for microphone including: a transistor including at least one of a JFET transistor and a MOSFET transistor, an input-impedance-network including a first terminal connected to a gate terminal of the transistor, a source resistor connected with its first terminal to the source terminal of the transistor and its second terminal to the ground terminal, a bypass capacitor (CS) connected in parallel to the source resistor, a load resistor (RD) including a first terminal connected to a drain terminal of the transistor, a charge pump generating a low voltage power supply (VCC_LOW) connected to a second terminal of the load resistor, and an inverted voltage (−VEE) connected to a first power supply terminal of an op amplifier, an op amplifier including a first input terminal connected to a reference voltage, a second input terminal connected to the load resistor through a differential bi-directional low-pass-filter, a first power supply terminal connected to the inverted voltage, a second supply terminal connected to main supply voltage, and an output terminal connected to a second terminal of the input impedance network through a second low pass filter, and an input electrets capacitor source connected in parallel to the input-impedance-network.

According to still another exemplary embodiment there is provided a device and a method for microphone including: a transistor including at least one of a JFET transistor and a MOSFET transistor, an input-impedance-network including a first terminal connected to a gate terminal of the transistor, a source resistor connected with its first terminal to the source terminal of the transistor and its second terminal to the ground terminal, a bypass capacitor (CS) connected in parallel to the source resistor, a load resistor (RD) including a first terminal connected to a drain terminal of the transistor, a charge pump generating a low voltage power supply (VCC_LOW) connected to a second terminal of the load resistor, and an inverted voltage (−VEE) connected to a first power supply terminal of an op amplifier, an op amplifier including a first input terminal connected to a reference voltage connected is series to a first output terminal of a differential bi-directional low-pass-filter, and a second input terminal connected to a second output terminal of the differential bi-directional low-pass-filter, where input terminals of the differential bi-directional low-pass-filter are connected in parallel to the load resistor, a first power supply terminal connected to the inverted voltage, a second power supply terminal connected to main supply voltage, and an output terminal connected to a second terminal of the input-impedance-network through a second low-pass-filter, and an input source including a MEMS capacitor including a first terminal connected to ground, and a second terminal connected to a first terminal of MEMS-bias-network, a MEMS-bias-network including a second terminal connected to a bias voltage (VBB), and a coupling capacitor including a first terminal connected to the second terminal of the MEMS capacitor and a second terminal connected to the gate terminal of the transistor.

Further according to another exemplary embodiment, the input-impedance-network includes a plurality of low-leakage diodes connected in series, where a cathode of a first diode is the first terminal of the input-impedance-network, an anode of the first diode is connected to a cathode of a second diode, and an anode of a last diode is the second terminal of the input impedance network.

Still further according to another exemplary embodiment, the input-impedance-network includes a plurality of low-leakage diodes connected in series, where an anode of a first diode is the first terminal of the input impedance network, a cathode of the first diode is connected to an anode of a second diode, a cathode of a last diode is the second terminal of the input-impedance-network.

Yet further according to another exemplary embodiment, the input-impedance-network includes a parallel diode network including a first diode network where a cathode of a first diode is the first terminal of the input-impedance-network, an anode of the first diode connected to a cathode of a second diode, an anode of the last diode is the second terminal of the input-impedance-network, and a second diode network where an anode of a first diode connected to the first terminal of the input-impedance-network, a cathode of the first diode connected to an anode of a second diode, and a cathode a last diode connected to the second terminal of the input impedance network.

Even further according to another exemplary embodiment, the input impedance network includes a plurality of sub-networks connected in series, and where a first terminal of a first sub-network is the first terminal of the input-impedance-network, a second terminal of the first sub-network is connected to a first terminal of a next sub-network, and a second terminal of a last sub-network is the second terminal of the input-impedance-network, where a sub-network includes a two identical low-leakage diodes connected in parallel in opposite polarity.

Additionally, according to another exemplary embodiment, the MEMS-bias-network includes a series of low-leakage diodes including a cathode of a first diode is the first terminal of the MEMS-bias-network, an anode of the first diode is connected to a cathode of a second diode, and an anode of a last diode is the second terminal of the MEMS-bias-network.

According to yet another exemplary embodiment the MEMS-bias-network includes a series of low-leakage diodes including an anode of a first diode is the first terminal of the MEMS-bias-network, a cathode of the first diode is connected to an anode of a second diode, and a cathode of a last diode is the second terminal of the MEMS-bias-network.

According still to another exemplary embodiment the MEMS-bias-network includes a parallel diode network including a first diode network including a cathode of a first diode is the first terminal of the MEMS-bias-network, an anode of the first diode connected to a cathode of a second diode, an anode of the last diode is the second terminal of the MEMS-bias-network, and a second diode network including an anode of a first diode connected to the first terminal of the MEMS-bias-network, a cathode of the first diode connected to an anode of a second diode, and a cathode a last diode connected to the second terminal of the MEMS-bias-network.

Further according to another exemplary embodiment the MEMS-bias-network includes a plurality of sub-networks connected in series, where a first terminal of a first sub-network is the first terminal of the MEMS-bias-network, a second terminal of the first sub-network is connected to a first terminal of a next sub-network, and a second terminal of a last sub-network is the second terminal of MEMS-bias-network, where each sub-network includes a two identical low-leakage diodes connected in parallel in opposite polarity.

Unless otherwise defined, all technical and scientific terms used herein have the same meaning as commonly understood by one of ordinary skill in the relevant art. The materials, methods, and examples provided herein are illustrative only and not intended to be limiting. Except to the extent necessary or inherent in the processes themselves, no particular order to steps or stages of methods and processes described in this disclosure, including the figures, is intended or implied. In many cases the order of process steps may vary without changing the purpose or effect of the methods described.

### BRIEF DESCRIPTION OF THE DRAWINGS

Various embodiments are described herein, by way of example only, with reference to the accompanying drawings. With specific reference now to the drawings in detail, it is stressed that the particulars shown are by way of example and for purposes of illustrative discussion of the embodiments only, and are presented in order to provide what is believed to be the most useful and readily understood description of the principles and conceptual aspects of the embodiment. In this regard, no attempt is made to show structural details of the embodiments in more detail than is necessary for a fundamental understanding of the subject matter, the description taken with the drawings making apparent to those skilled in the art how the several forms and structures may be embodied in practice.

In the drawings:

FIG. 1 is a simplified block diagram of a wakeup receiver;

FIG. 2 is a simplified flow chart of a transceiver state machine;

FIG. 3 is a simplified electric schematic of a microphone element connected to a microphone buffer based on a JFET transistor;

FIG. 4 is an electric schematic of an AC equivalent circuit for noise/gain analysis of the circuit of FIG. 3

FIG. 5 is a simplified electric schematic of a first option of a buffer circuit eliminating RG in the buffer and decreasing noise due to leakage;

FIG. 6 is a simplified electric schematic of a second option of a buffer circuit eliminating RG in the buffer and decreasing noise due to leakage;

FIG. 7 is a simplified electric schematic of a third option of a buffer circuit eliminating RG in the buffer and decreasing noise due to leakage;

FIG. 8 is a simplified electric schematic of a fourth option of a buffer circuit eliminating RG in the buffer and decreasing noise due to leakage;

FIG. 9 is a simplified illustration of AC and noise-equivalent circuit of FIG. 5;

FIG. 10 is a simplified illustration of AC and noise equivalent circuit of FIG. 7;

FIG. 11 is a simplified illustration of the distortion due to the diodes network;

FIG. 12 is a simplified illustration of an Electret Condenser Microphone (ECM) ultra-low-noise ultra-low-power microphone with feedback from source;

FIG. 13 is a simplified illustration of an Electret equivalent circuit;

FIG. 14 is a simplified illustration of an Electret Condenser Microphone (ECM) ultra-low-noise ultra-low-power microphone with feedback from drain;

FIG. 15 is a simplified illustration of a Micro Electrical Mechanical System Microphone ultra-low-noise ultra-low-power microphone with feedback from source;

FIG. 16 is a simplified illustration of a Micro Electrical Mechanical System Microphone ultra-low-noise ultra-low-power microphone with feedback from drain; and

FIG. 17 is a simplified electric schematic of an ultra-low-noise VBB biasing circuit.

### DETAILED DESCRIPTION

The invention in embodiments thereof comprises systems and methods for ultra-low-power and an ultra-low-noise microphone buffer. The principles and operation of the devices and methods according to the several exemplary embodiments presented herein may be better understood with reference to the following drawings and accompanying description.

Before explaining at least one embodiment in detail, it is to be understood that the embodiments are not limited in its application to the details of construction and the arrangement of the components set forth in the following description or illustrated in the drawings. Other embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document may not be to any scale. Different figures may use different scales and different scales can be used even within the same drawing, for example different scales for different views of the same object or different scales for the two adjacent objects.

The purpose of embodiments described below is to provide at least one system and/or method for ultra-low-power and an ultra-low-noise microphone buffer. More particularly, but not exclusively, the microphone buffer may be used with battery-operated devices that have relatively long time operating in standby mode, and/or where immediate wakeup procedure is required. However, the systems and/or methods as described herein may have other embodiments in similar technologies of local area communication.

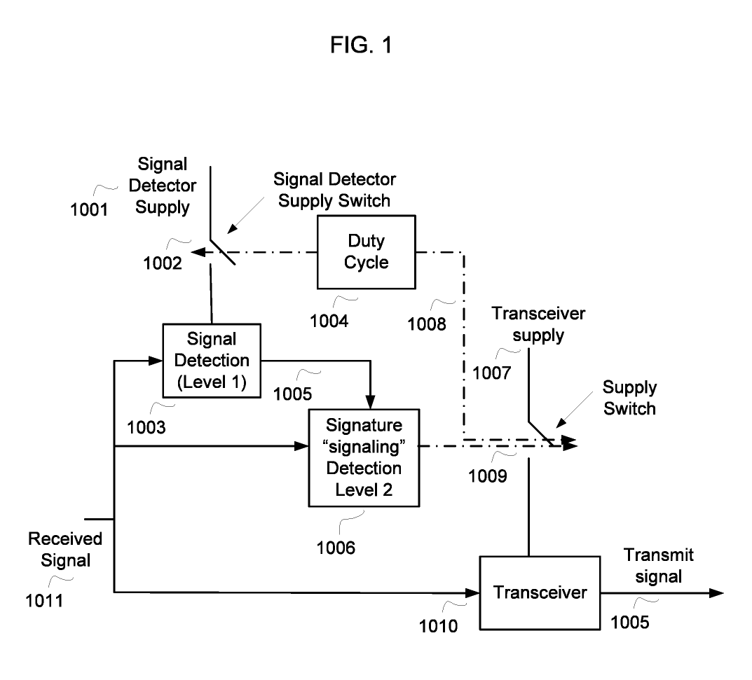

FIG. 1 is a simplified block diagram of a wakeup receiver implementation, according to one exemplary embodiment.

Signal supply 1001, could be connected to signal detection level 1 1003 for detection of signal presence 1011 at some bandwidth, If a signal exist signal 1005 turns on a signature/valid marker detection circuit 1006, which normally consumes high power. If the marker is valid signal 1009 switches on the transceiver power supply 1007, turning on the transceiver 1010. Alternatively, the wakeup receiver can periodically turn on the signal detection power supply using signal 1002. At that time the signal 1011 presence testing is done.

As stated above, although the design of FIG. 1 looks promising, implementing a periodically turn-on wakeup receiver, as done in Bluetooth Low Energy (BLE), may cause a delayed responsive transceiver. Still, such receiver can consume a lot of power. A typical BLE implementation using a CR2032 battery typically operates for 8-14 months. The CR2032 battery may be too big for some devices, such as glasses, button of pens or shirt or a toothbrush. Moreover even if an envelope detector is implemented, the number of false alarm will be high, as ISM band is highly populated, and it would not be easy to implement a bandwidth signal presence envelope detector.

Still there is a requirement for some devices to work for a few years and still from a much smaller battery than the CR2032 (a 235 mAh battery), acoustic communication can allow this especially if the 6000 Hz band is divided into smaller bands like 500 Hz acoustic communication is smaller by 2000 compared to RF communication.

Still the signal transducer from acoustic to electrical signal is the microphone—microphone today consume 17 ua-500 ua—if we use for example a battery which is 2.5 mm×2.5 mm×1 mm that if we compare this battery to the CR2032 which is with diameter of 20 mm and thickness of 3 mm we have battery which is 160 less in volume or we have about 1.47 mah battery (here we scale the 235 mah of about 1000 mm̂3 of the CR2032 with our 2.5 mm×2.5 mm×1 mm) then the microphone by itself—if we use the 17 ua will draw the whole energy from our small battery—2.5 mm×2.5 mm×1 mm—in about 90 hours.

Moreover, the microphone today would have Signal to Noise Ratio (SNR) of about 68 dB which limits the communication range, therefore there is a need to have extremely low power wakeup receiver such receiver can is preferably consume 50 nWatt-100 nWatt and from a 3V battery. This would mean a current consumption of 17 nA-33 nA, which may provide 10 years of operation if the power consumption is 50 nWatt.

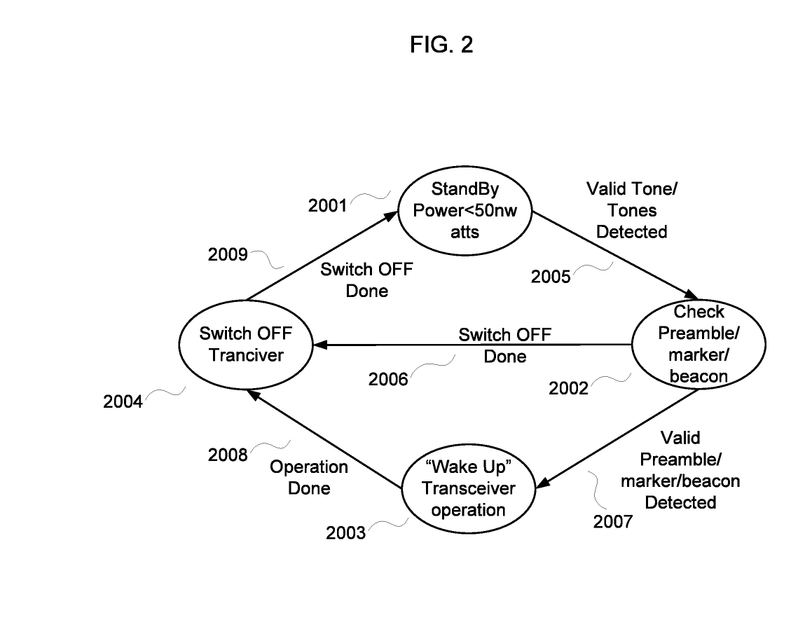

FIG. 2 is a simplified flow chart of a transceiver state machine, according to one exemplary embodiment.

As shown in FIG. 2, the first state 2001 may consume 50 nWatt. In this state an acoustic signal is searched using ultra-low-power microphone, and ultra-low-power signal detection circuit which is relatively feasible because of the inherit fact of the extremely low frequency of the acoustic signal, when an acoustic signal presence is detected 2005, the state machine moves to the check preamble/marker/beacon state 2002, if this was a false alarm 2006, the state machine goes the switch off state 2004, sends a switch off signal 2009 and goes back to the first state 2001, on the other hand if the preamble/marker/beacon is valid 2007, the acoustic transceiver is waked up and the state machine goes to the “Wake Up” state 2003, where the transceiver performs the required operation.

As suggested above the acoustic based transceivers, of an IoT or IoE devices are not a content based transceivers and need to work only “On Demand” therefore most of the time these transceivers would be most of the time in standby state—2001 of FIG. 2.

Microphones are important as an input device for acoustic audio waves for the increasing market of the smartphones/tablets/cellphones, the new microphones would need to have higher SNR for better acoustic echo canceling and better audio quality in one hand and on the other hand to be extremely low power to allow hand free acoustic audio activation—like the android “OK Google”.

Moreover, for the IoT IoE devices microphones are important as an “antenna” converting the acoustic communication signal to electrical signal, to allow many years of operation these microphones need to consume less power than 50 nWatt and to allow large communication range these microphones would need to have a better SNR than 70 db that currently allow a communication of up to 20-30 meters using 96 dB SPL signal.

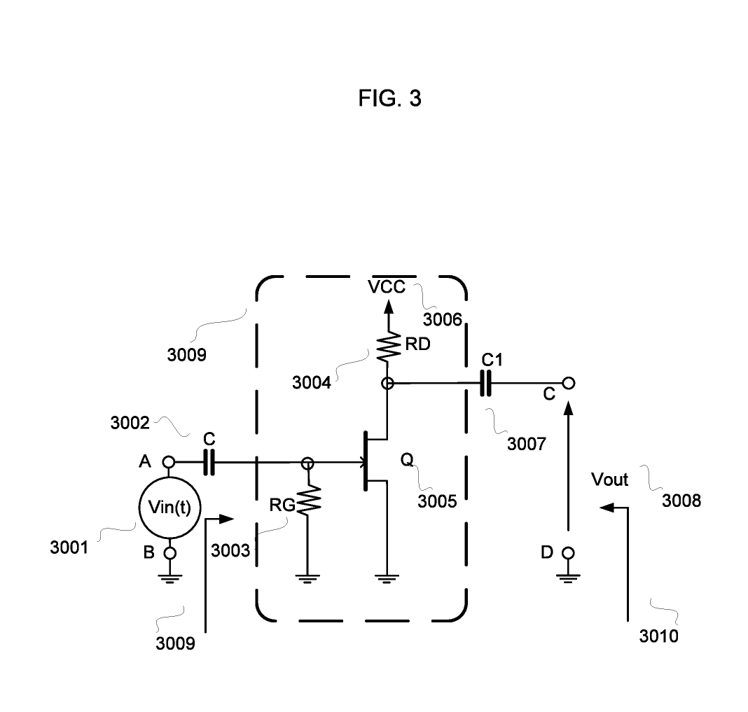

FIG. 3 is a simplified electric schematic of a microphone element, connected to a microphone buffer based on a JFET transistor, according to one exemplary embodiment.

FIG. 3 describes a microphone element 3001, described here as a source of signal, usually coupled to the microphone buffer 3009 via a coupling capacitor 3002, the microphone buffer 3009, includes a gate bias resistor RG 3003, active element 3005, JFET transistor—but could be MOSFET transistor as well, a load resistor RD 3004 and a power supply VCC 3006, the output is coupled via a coupling capacitor.

The buffer 3009, may be used to transfer the signal from the acoustic transducer source 3001, showing a low capacitance at the input 3009, and low output impedance at the output 3010.

Noise Gain Analysis

The following analysis may be suitable for any kind of microphone such as, for example, Electret Condenser Microphone (ECM), or a Micro Electronic Mechanical Systems (MEMS) microphone.

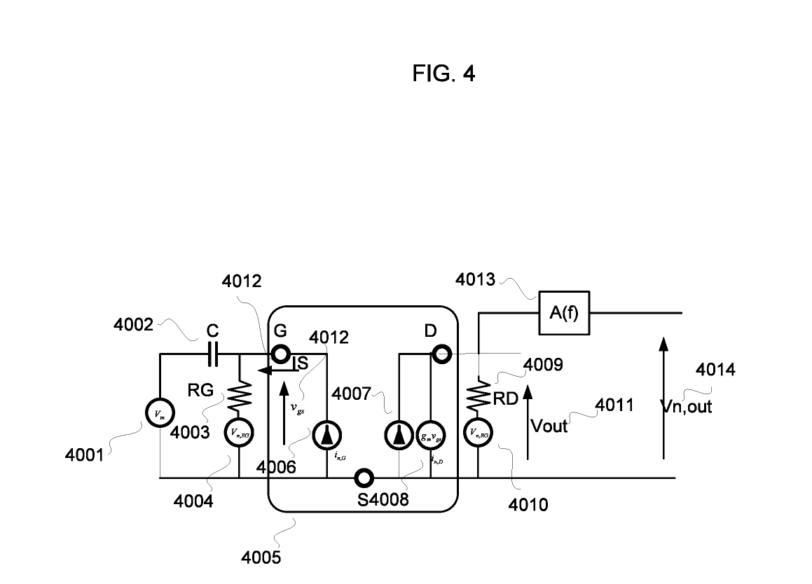

FIG. 4 is a electric schematic of an AC equivalent circuit for noise/gain analysis of the circuit of FIG. 3, according to one exemplary embodiment.

The AC equivalent circuit is a model circuit useful for computing variable signal relations, and particularly as small signals.

We assume that the active element 3005, JFET of FIG. 3 is in saturation mode—i.e. where we get gain—

As described by FIG. 4, there are a few noise sources for the circuit of FIG. 3:

RG: Thermal noise from RG 4003, described by a serial voltage source 4004 and the noise is given by:

V_{n,RG}²=4KTR_{G}Δf Eq. 1

where K is the Boltzmann constant and T is temperature in Kelvin degrees.

RD: Thermal noise from RD 4009, described by a serial voltage source 4004 and the noise is given by:

V_{n,RD}²=4KTR_{D}Δf Eq. 2

where K is the Boltzmann constant and T is temperature in Kelvin degrees.

Current noise in the drain source—here we neglect the 1/f noise—which appears at very low frequencies, the drain source current noise is given by:

$${i}_{n , d}^{2} = \frac{8}{3} {KTg}_{m} Δ f \qquad Eq . 3$$

Current noise from the gate 4006 and is given by:

i_{n,d}²=2I_{S}qΔf Eq. 4

The noise in microphones is calculated taking into account—so called A weighted filter 4013, this filter 4013, simulates in some sense the human ears frequency response—this response is given by Eq. 5, the output of the filter 4014 denoted by Vn,out.

$$A ( f ) = {10}^{( 2 / 20 )} \frac{{12200}^{2} {f}^{4}}{( {f}^{2} + {20.6}^{2} ) ( {f}^{2} + {12200}^{2} ) \sqrt{( {f}^{2} + {107.7}^{2} ) ( {f}^{2} + {739.7}^{2} )}} \qquad Eq . 5$$

Vout 4010 is given by:

$${v}_{out} = - {g}_{m} {v}_{in} ( \frac{j ω {R}_{G} C}{1 + j ω {R}_{G} C} ) {R}_{D} \qquad Eq . 6$$

while Vn,out 4014 is given by

$${v}_{n , out} ( f ) \sqrt{Δ f} = {g}_{m} \sqrt{4 {KTR}_{G} Δ f} ( \frac{1}{1 + j ω {R}_{G} C} ) {R}_{D} A ( f ) -- {g}_{m} \sqrt{2 {I}_{S} q Δ f} ( \frac{{R}_{G}}{1 + j ω {R}_{G} C} ) {R}_{D} A ( f ) + {R}_{D} \sqrt{\frac{8}{3} {KTg}_{m} Δ f} A ( f ) + \sqrt{4 {KTR}_{D} Δ f} A ( f ) \qquad Eq . 7$$

where ω=2πf.

Assuming ωR_{G}C»1 in Eq. 6 and Eq. 7 becomes:

$$\begin{matrix} {v}_{out} = - {g}_{m} {v}_{i n} {R}_{D} & Eq . 8 \\ {v}_{n , out} ( f ) \sqrt{Δ f} \approx \approx - {g}_{m } \sqrt{4 {KTR}_{G} Δ f} ( \frac{1}{j 2 π {fR}_{G} C} ) {R}_{D} A ( f ) - {g}_{m} \sqrt{2 {I}_{S} q Δ f} ( \frac{1}{j 2 π fC} ) {R}_{D} A ( f ) + {R}_{D} \sqrt{\frac{8}{3} {KTg}_{m} Δ f} A ( f ) + \sqrt{4 {KTR}_{D} Δ f} A ( f ) & Eq . 9\end{matrix}$$

In order to fine the Root Mean Square noise, one should add the RMS noise elements in a bandwidth on f1=0 Hz to f2=20000 Hz or:

$${v}_{n , out}^{2} = {\int }_{{f}_{1}}^{{f}_{2}} {\vert {v}_{n , out} ( f ) \vert}^{2} df = {g}_{m}^{2} 4 {KTR}_{D}^{2} ( \frac{1}{4 {π}^{2} {R}_{G} {C}^{2}} ) {\int }_{{f}_{1}}^{{f}_{2}} \frac{{\vert A ( f ) \vert}^{2}}{{f}^{2}} df + {g}_{m}^{2} 2 {I}_{S} {qR}_{D}^{2} ( \frac{1}{4 {π}^{2} {C}^{2}} ) {\int }_{{f}_{1}}^{{f}_{2}} \frac{{\vert A ( f ) \vert}^{2}}{{f}^{2}} df ++ \frac{8}{3} {KTg}_{m} {R}_{D}^{2} {\int }_{{f}_{1}}^{{f}_{2}} {\vert A ( f ) \vert}^{2} df + 4 {KTR}_{D} {\int }_{{f}_{1}}^{{f}_{2}} {\vert A ( f ) \vert}^{2} df \qquad Eq . 10$$

Or if:

$$\begin{matrix} {ξ}_{1} = {\int }_{{f}_{1}}^{{f}_{2}} \frac{{\vert A ( f ) \vert}^{2}}{{f}^{2}} df , {ξ}_{2} = {\int }_{{f}_{1}}^{{f}_{2}} {\vert A ( f ) \vert}^{2} df \\ Then \text{:} & Eq . 11 \\ {v}_{n , out}^{2} = {\int }_{{f}_{1}}^{{f}_{2}} {\vert {v}_{n , out} ( f ) \vert}^{2} df = {g}_{m}^{2} 4 {KTR}_{D}^{2} ( \frac{1}{4 {π}^{2} {R}_{G} {C}^{2}} ) {ξ}_{1} + {g}_{m}^{2} 2 {I}_{S} {qR}_{D}^{2} ( \frac{1}{4 {π}^{2} {C}^{2}} ) {ξ}_{1} ++ \frac{8}{3} {KTg}_{m} {R}_{D}^{2} {ξ}_{2} + 4 {KTR}_{D} Δ f {ξ}_{2} & Eq . 12\end{matrix}$$

For f1=0 Hz, f2=20000 Hz one can show using Eq. 5 that:

ξ₁=0.0026, ξ₂=12474 Eq. 13

As the gain is defined by G=gₘR_{D} then Eq. 12 could be written as:

$${v}_{n , out}^{2} = {\int }_{{f}_{1}}^{{f}_{2}} {\vert {v}_{n , out} ( f ) \vert}^{2} df = {G}^{2} 4 KT ( \frac{1}{4 {π}^{2} {R}_{G} {C}^{2}} ) {ξ}_{1} + {G}^{2} 2 {I}_{S} q ( \frac{1}{4 {π}^{2} {C}^{2}} ) {ξ}_{1} ++ G \frac{8}{3} {KTR}_{D} {ξ}_{2} + 4 {KTR}_{D} {ξ}_{2} \qquad Eq . 14$$

And the noise equivalent at the input is:

$${v}_{n , i n}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} df = 4 KT ( \frac{1}{4 {π}^{2} {R}_{G} {C}^{2}} ) {ξ}_{1} + 2 {I}_{S} q ( \frac{1}{4 {π}^{2} {C}^{2}} ) {ξ}_{1} + \frac{8}{3 G} {KTR}_{D} {ξ}_{2} + \frac{4 {KTR}_{D} {ξ}_{2}}{{G}^{2}} \qquad Eq . 15$$

Analysis of Noise Terms

For

$$4 KT ( \frac{1}{4 {π}^{2} {R}_{G} {C}^{2}} ) {ξ}_{1}$$

it is clear that having large C and large RG will decrease the noise, however for ECM or MEMS microphones C=5 pf-10 pf this is due the small size RG is usually 25M-100M so for prior art microphone with RG=100M.

$$\sqrt{4 KT ( \frac{1}{4 {π}^{2} {R}_{G} {C}^{2}} ) {ξ}_{1}} = 10.4 uv \qquad Eq . 16 A$$

Increasing RG to 1G will give a noise of about 3 uv for RG=1G and microphone sensitivity of −38 dBv=12.6 mv the reflected (not taking into account other terms) SNR from this noise is

$$20 {log}_{10} ( \frac{12.6 mv / \sqrt{2}}{3 uv} ) = 69.45 dB .$$

Tables 1 and 1a summarize the A weighted noise and SNR for various C and RG values.

TABLE 1
Equivalent A weighted noise at the input
induced by Rg for various Rg and C values

| | | C | | | | |
|---|---|---|---|---|---|---|
| Rg | | 5 pf | 10 pf | 30 pf | 56 pf | 100 pf |
| 25 | Mohm | 41.77 uv | 20.89 uv | 6.96 uv | 37.3 uv | 2.09 uv |
| 100 | Mohm | 20.89 uv | 10.44 uv | 3.48 uv | 18.6 uv | 1.04 uv |
| 1 | Gohm | 6.6 uv | 3.3 uv | 1.1 uv | 5.9 uv | 0.33 uv |
| 10 | Gohm | 2.09 uv | 1.04 uv | .35 uv | 1.9 uv | 0.1 uv |

TABLE 1a
SNR with A weighted noise at the input induced
by Rg for various Rg and C values

| | | C | | | | |
|---|---|---|---|---|---|---|
| Rg | | 5 pf | 10 pf | 30 pf | 56 pf | 100 pf |
| 25 | Mohm | 46.6[dB] | 52.6[dB] | 62.16[dB] | 67.6[dB] | 72.6[dB] |
| 100 | Mohm | 52.6[dB] | 58.6[dB] | 68.16[dB] | 73.6[dB] | 78.6[dB] |
| 1 | Gohm | 62.6[dB] | 68.6[dB] | 78.16[dB] | 83.6[dB] | 88.6[dB] |
| 10 | Gohm | 72.6[dB] | 78.6[dB] | 88.16[dB] | 93.6[dB] | 98.6[dB] |

For

$$2 {I}_{S} q ( \frac{1}{4 {π}^{2} {C}^{2}} ) {ξ}_{1}$$

where Is, 4012 is the leakage current, it is clear that having smaller leakage current will decrease the noise from the JFET hate leakage current, C again is 5 pf-10 pf, for Is=1000 pa one get:

$$\sqrt{2 {I}_{S} q ( \frac{1}{4 {π}^{2} {C}^{2}} ) {ξ}_{1}} = 14.5 uv \qquad Eq . 16 B$$

And for Is=1 pa one gets 0.46 uv and for Is=0.2 pa one gets 0.21 uv for microphone with −38 dBv=12.6 mv sensitivity and IS=1000 pA, 1 pA and 0.2 pA the reflected SNR is:

$$Is = 1000 pa -> 20 {log}_{10} ( \frac{12.6 mv / \sqrt{2}}{14.5 uv} ) = 55 dB$$

$$Is = 1 pa -> 20 {log}_{10} ( \frac{12.6 mv / \sqrt{2}}{0.46 uv} ) = 85 dB$$

$$Is = 0.2 pa -> 20 {log}_{10} ( \frac{12.6 mv / \sqrt{2}}{0.21 uv} ) = 92.6 dB$$

Tables 2 and 2a summarize the input-equivalent A-weighted noise and the associated SNR for −38 dBv sensitivity.

TABLE 2
Equivalent A weighted noise at the input induced by JFET
leakage noise current for different leakage and C values

| | C | | | | |
|---|---|---|---|---|---|
| Is | 5 pf | 10 pf | 30 pf | 56 pf | 100 pf |
| 1000 pa | 29.03 uv | 14.52 uv | 4.84 uv | 2.59 uv | 1.45 uv |
| 100 pa | 9.18 uv | 4.59 uv | 1.53 uv | 0.82 uv | 0.46 uv |
| 2 pa | 1.3 uv | 0.65 uv | 0.22 uv | 0.12 uv | 0.06 uv |
| 1 pa | 0.92 uv | 0.46 uv | 0.15 uv | 0.08 uv | 0.05 uv |

TABLE 1a
SNR with A weighted noise at the input induced by JFET leakage
noise current for different leakage and C values

| | C | | | | |
|---|---|---|---|---|---|
| Rg | 5 pf | 10 pf | 30 pf | 56 pf | 100 pf |
| 1000 pa | 49.74[dB] | 55.76[dB] | 65.30[dB] | 70.72[dB] | 75.76[dB] |
| 100 pa | 59.74[dB] | 65.76[dB] | 75.30[dB] | 80.72[dB] | 85.76[dB] |
| 2 pa | 76.3[dB] | 82.75[dB] | 92.30[dB] | 97.71[dB] | 102.75[dB] |
| 1 pa | 79.74[dB] | 85.76[dB] | 95.30[dB] | 100.72[dB] | 105.76[dB] |

For other two terms

$$\frac{8}{3 G} {KTR}_{D} {ξ}_{2} \text{and} \frac{4 {KTR}_{D} {ξ}_{2}}{{G}^{2}}$$

we assume a JFET with IDSS=0.5 mA Vp=−1V and RD=1000 Ohm which are typical values (here we neglected the Cgs that gives attenuation at the input by 2 and therefore usually one selects RD=2000 Ohm using this it is clear that

$${g}_{m} = \frac{2}{{V}_{P}} \sqrt{{I}_{D} {I}_{DSS}} = \frac{2 {I}_{DSS}}{{V}_{P}} \{ at {V}_{GS} = 0 \} = 0.001 {( ohm )}^{- 1}$$

$$and G = {g}_{m} {R}_{D} = 1$$

For

$$\frac{8}{3 G} {KTR}_{D} {ξ}_{2}$$

it is clear that smaller RD will decrease the noise as well as larger G, this is possible by increasing the current, for typical ECM or MEMS microphones.

$$\sqrt{\frac{8}{3 G} {KTR}_{D} {ξ}_{2}} = 0.37 uv \qquad Eq . 16 C$$

And for −38 dBv=12.6 mv microphone the reflected SNR here is

$$20 {log}_{10} ( \frac{12.6 mv / \sqrt{2}}{0.37 uv} ) = 87.6 dB .$$

This number could be easily increased by lowering RD, by using increased IDSS JFET, for example by using JFET with IDSS=5 ma we can use RD=100 Ohm and in this case the SNR will be

$$20 {log}_{10} ( \frac{12.6 mv / \sqrt{2}}{0.123 uv} ) = 97.2 dB .$$

For

$$\frac{4 {KTR}_{D} {ξ}_{2}}{{G}^{2}}$$

it is clear that decreasing RD and increasing G will decrease this term, for typical ECM or MEMS microphones we have

$$D \sqrt{\frac{4 {KTR}_{D} {ξ}_{2}}{{G}^{2}}} = 0.45 uv \qquad Eq . 16$$

Which, for −38 dBv microphone sensitivity reflects an SNR of

$$20 {log}_{10} ( \frac{12.6 mv / \sqrt{2}}{0.45 uv} ) = 85.9 dB .$$

as before by decreasing RD by 10 by using JFET with

IDSS=5 ma the reflected SNR would become

$$20 {log}_{10} ( \frac{12.6 mv / \sqrt{2}}{0.45 uv} ) = 96 dB$$

Conclusions:

As one can see the limiting factor for the SNR is the RG, then the leakage current while the last two term are easily decreased by using JFET with larger IDSS and hence smaller RD, on the other hand C could be increased—by putting a parallel to gate and source a second capacitor, that will decrease the noise coming from RG 4003 and the noise due to the leakage IS 4012, the capacitor will give attenuation that could be compensated by increasing the gm transconductence of the JFET 4005, by increasing the drain current.

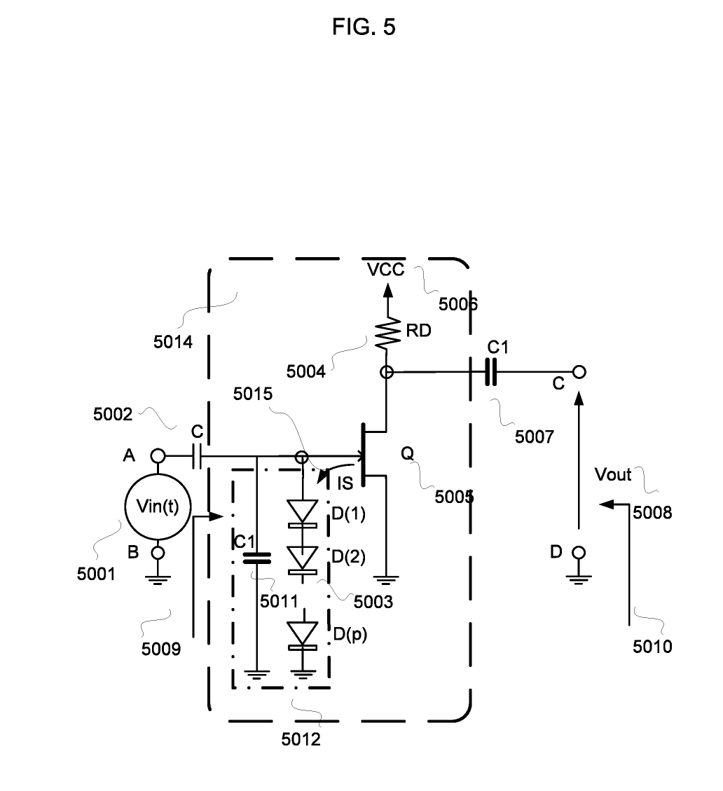

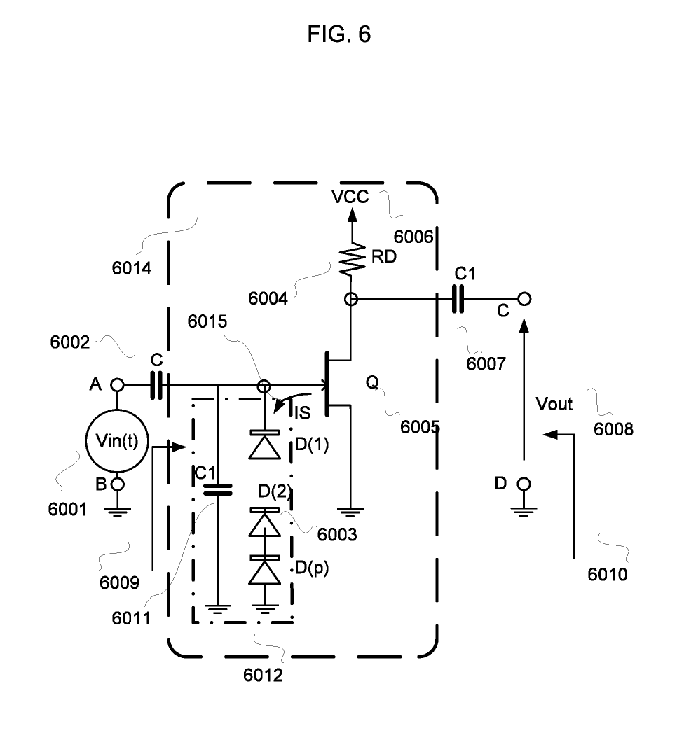

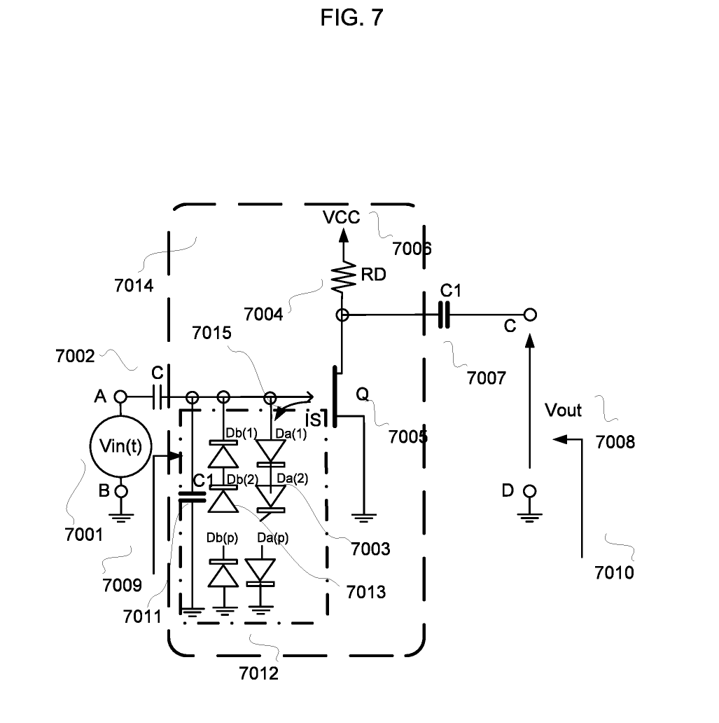

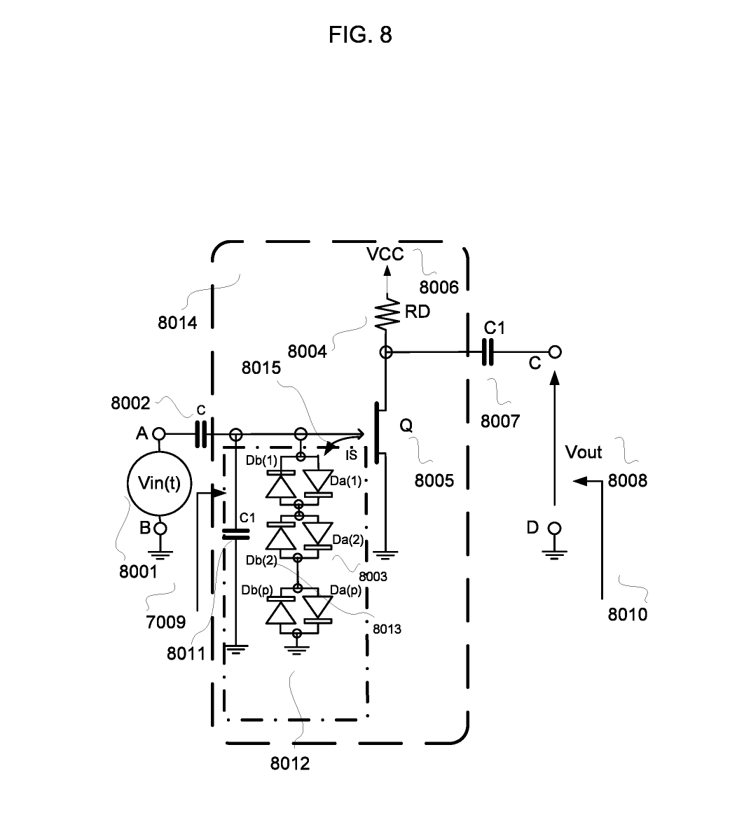

FIG. 5, FIG. 6, FIG. 7 and FIG. 8, describe four optional solutions for the RG problem with a possible parallel capacitor C1.

FIG. 5 is a simplified electric schematic of a first option of a buffer circuit eliminating RG in the buffer and decreasing noise due to leakage, according to one exemplary embodiment.

FIG. 6 is a simplified electric schematic of a second option of a buffer circuit eliminating RG in the buffer and decreasing noise due to leakage, according to one exemplary embodiment.

FIG. 7 is a simplified electric schematic of a third option of a buffer circuit eliminating RG in the buffer and decreasing noise due to leakage, according to one exemplary embodiment.

FIG. 8 is a simplified electric schematic of a fourth option of a buffer circuit eliminating RG in the buffer and decreasing noise due to leakage, according to one exemplary embodiment.

Circuits of FIG. 5, FIG. 6, FIG. 7 and FIG. 8 are based on a network of diodes 6012, 7012, 8012 and 9012 and capacitor C1 5011, 6011, 7011 and 8011.

Analysis of Serial Diodes Network Connection

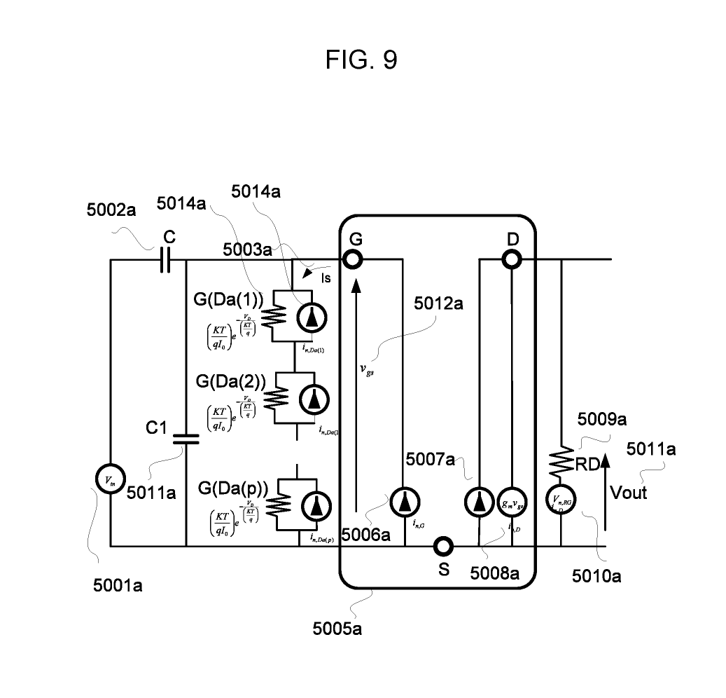

FIG. 9 is a simplified illustration of AC and noise-equivalent circuit of FIG. 5, according to one exemplary embodiment.

FIG. 5A describes in details the diodes 5003 with the capacitor C1 5011. The noise of each diode Da(1), Da(2) . . . Da(p) 5003 of FIG. 5 is given by:

i_{n,Da(k)}²=(2I_{S}+I₀)qΔf Eq. 17

Diode Small Signal Resistance

The small signal diode resistance is given by

$${[ \frac{{I}_{0}}{( \frac{KT}{q} )} {e}^{\frac{{V}_{D}}{( \frac{KT}{q} )}} ]}^{- 1} = ( \frac{KT}{{qI}_{0}} ) {e}^{- \frac{{V}_{D}}{( \frac{KT}{q} )}} \approx ( \frac{KT}{{qI}_{0}} ) {( \frac{KT}{{qV}_{D}} )}_{Forsmall {V}_{D} ≪ \frac{KT}{q}}$$

If a diode with I₀≈I_{S} is selected then

$${V}_{D ( DC )} = \frac{KT}{q} ln ( 2 ) = 0.69 \frac{KT}{q} = 17.3 {mv}_{at 25 deg}$$

In this case the diode small signal resistance is given by

$$( \frac{KT}{2 {qI}_{S}} ) .$$

It may be useful to select diode that do not have higher leakage current than the Is, which may help with reduction of diode noise. If I₀≈I_{S}, then the DC voltage on the diode will be small, such that using 10-20 diodes in series will not create high voltage drop on the diodes.

Diode Current Noise Calculation and Reduction

The reason for connecting serial diodes is to reduce the distortion resulting from using the diode. First we show that connecting diodes in series may reduce the total diode noise.

One can transform the diodes 5003, circuit of FIG. 9, using the Thevenin theorem and get the following total current with the following total resistance.

$$\begin{matrix}{i}_{n , diodes} = \frac{\sqrt{\begin{matrix}\begin{matrix}( 2 {I}_{S} + {I}_{0} ) q Δ {f ( \frac{KT}{2 {qI}_{s}} )}^{2} + \\ ( 2 {I}_{S} + {I}_{0} ) q Δ {f ( \frac{KT}{2 {qI}_{s}} )}^{2} + … +\end{matrix} \\ ( 2 {I}_{S} + {I}_{0} ) q Δ {f ( \frac{KT}{2 {qI}_{s}} )}^{2}\end{matrix}}}{p ( \frac{KT}{2 {qI}_{s}} )} \\ == \frac{( 2 {I}_{S} + {I}_{0} ) q Δ {f ( \frac{KT}{2 {qI}_{s}} )}^{2}}{\sqrt{p}}\end{matrix} \qquad Eq . 18$$

And the total resistance is

$$p ( \frac{KT}{2 {qI}_{s}} ) ,$$

this does not gives any thermal noise it is just the slope of the diode current, having C1.

The total current noise is the square sum of the diode noise and the gate leakage noise 5014a and is given by:

$${i}_{n , diodes + jfet}^{2} = \frac{( 2 {I}_{S} + {I}_{0} ) q Δ f}{p} + 2 {I}_{S} q Δ f \approx 2 {I}_{S} q Δ f for p \geq 10 \qquad Eq . 19$$

We can conclude that Eq. 15 now will take the form

$$\begin{matrix}{v}_{n , in}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} df \\ = 2 {I}_{S} q ( \frac{1}{4 {{π}^{2} ( C + {C}_{1} )}^{2}} ) {ξ}_{1} + \\ \frac{8}{3 G} {KTR}_{D} {{ξ}_{2} [ \frac{( C + {C}_{1} )}{C} ]}^{2} + \\ {\frac{4 {KTR}_{D} {ξ}_{2}}{{G}^{2}} [ \frac{( C + {C}_{1} )}{C} ]}^{2}\end{matrix} \qquad Eq . 20$$

One can see from equation 20, that C1 helps with reducing the current noise from the PN junction of the JFET and the diode noise, also connecting serial diodes helps with reducing the diode current noise, in effect the noise from the JFET current at the output 5007a and the noise from RD at the output 5010a is reflected to the input by a factor greater than

$${1 [ \frac{( C + {C}_{1} )}{C} ]}^{2}$$

for 1 pa leakage current we had Is=1 pa→

$$20 {log}_{10} ( \frac{12.6 mv / \sqrt{2}}{0.46 uv} ) = 85 dB$$

it is possible to increase this term by 10 dB by adding C1=2C, this requires that G will compensate the

$${[ \frac{( C + {C}_{1} )}{C} ]}^{2}$$

so this requires that G=10, still having Rd=100 ohm, this requires gm=0.1, or Id=100 ma, this is possible when using JFET with IDSS=100 ma.

Distortion Analysis

The equation of a diode is given by Eq. 21

$${I}_{D} = {I}_{0} ( {e}^{\frac{{V}_{D}}{( \frac{KT}{q} )}} - 1 ) = {I}_{0} ( ( \frac{{V}_{D}}{{V}_{T}} ) + \frac{1}{2 !} {( \frac{{V}_{D}}{{V}_{T}} )}^{2} + \frac{1}{3 !} {( \frac{{V}_{D}}{{V}_{T}} )}^{3} + \frac{1}{4 !} {( \frac{{V}_{D}}{{V}_{T}} )}^{4} … ) = {I}_{0} ( ( x ) + \frac{1}{2 !} {( x )}^{2} + \frac{1}{3 !} {( x )}^{3} + \frac{1}{4 !} {( x )}^{4} … ) \\ where {V}_{T} = \frac{KT}{q} and x = \frac{{V}_{D}}{{V}_{T}} \qquad Eq . 21$$

It is clear that for 1 pa-10 pa the impedance of a diode is about 25 mv/(2*1e−12)=12.5 Gohm, which means that all Von will be developed if we have C=10 pf 5002a at even low frequencies like 100 Hz, also it is known that the voltage on a microphone acoustic element is about its sensitivity which is about 12 mv this means that 12 mv/25 mc=x=0.5 will generate relatively high distortion, by adding several diodes the Vin voltage is divided over all diodes, and hence by having for example p=25 we have x=0.5 mV/25 mV= 1/50, this means that the next that the distortion will come from

$$\frac{1}{2 !} {( \frac{{V}_{D}}{{V}_{T}} )}^{2} ,$$

as

$$\frac{1}{2 !} {( \frac{{V}_{D}}{{V}_{T}} )}^{2} = \frac{1}{2 !} {( \frac{{V}_{D} ( dc ) + Vin / P}{{V}_{T}} )}^{2} = \frac{1}{2 !} ( \frac{{V}_{D} ( dc )}{{V}_{T}} + 2 \frac{{V}_{D} ( dc )}{{V}_{T}} \frac{Vin}{P} + {( \frac{Vin / P}{{V}_{T}} )}^{2} )$$

Which shows that the distortion current is I₀

$$\frac{1}{2 !} {( \frac{Vin / P}{{V}_{T}} )}^{2}$$

for I0=10 pa, C=10 pf and f=100 Hz, p=1 and max sensitivity the distortion voltage would be 24 μV with 14 mV (which is −40 dV).

Analysis of serial diodes network connection of FIG. 7 and FIG. 8

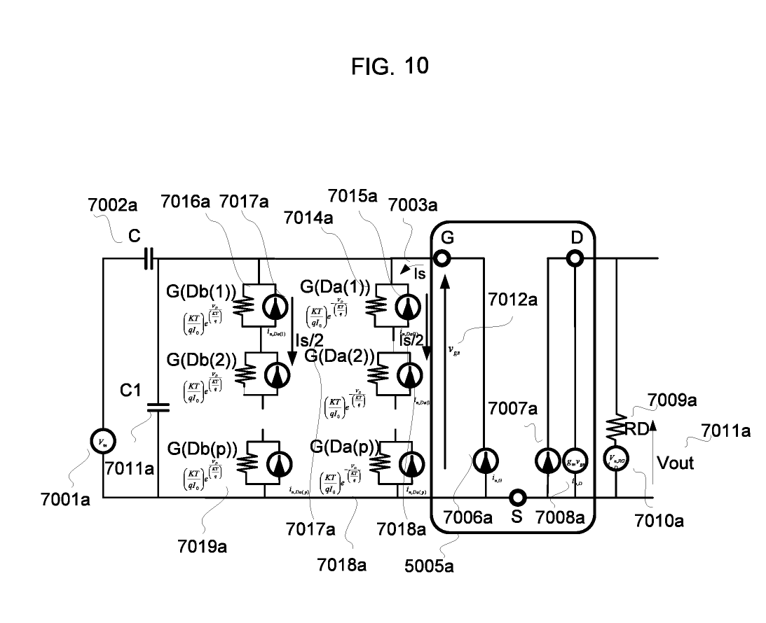

FIG. 10 is a simplified illustration of AC and noise equivalent circuit of FIG. 7, according to one exemplary embodiment.

FIG. 7A describes in details the diodes 7003, 7013 with the capacitor C1 7011.

In FIG. 7, a dual branch network of p diodes per each network is connected between the gate (input) and ground, the first network 7003 and a second network 7013, basically if Vgs=V, then each diode of the first network 7003 gets a voltage of V/p while each diode of the second network gets −V/p as V is very small, then the current flowing on the first network is equal to about

$${I}_{0} ( ( V / p ) + \frac{1}{2 !} {( V / p )}^{2} + \frac{1}{3 !} {( V / p )}^{3} + \frac{1}{4 !} {( V / p )}^{4} … )$$

And for the second network 7013

$$- {I}_{0} ( ( V / p ) - \frac{1}{2 !} {( V / p )}^{2} + \frac{1}{3 !} {( V / p )}^{3} - \frac{1}{4 !} {( V / p )}^{4} … )$$

With V/p is the voltage across Da(1), Da(2) . . . Da(p) the first diode branch 7015a and −V/p is the voltage across Db(1), Db(2) . . . Db(p) the second diode branch 7017a.

Part of the JFET leakage is 7003a will flow through the first branch 7015a and part will flow through the second branch 7017a.

The noise of each diode Da(1), Da(2) . . . Da(p) 7003 of FIG. 7 is given by:

i_{n,Da(k)}²=(2αI_{S})qΔf Eq. 22

where αI_{S} is the current flowing into the first diode branch from the JFET leakage.

The reason for connecting serial diodes is to reduce the distortion. The input voltage V would be divided by P for each diode as well as reducing the noise resulting from the diode noise current, first we show that connecting a serial diodes actually reduces the total diode noise.

One can transform the diodes of branch 7003 of the circuit of FIG. 7A using the Thevenin theorem and get the following total current with the following total resistance.

$${i}_{n , diodes} = \frac{\sqrt{\begin{matrix}( 2 α {I}_{S} + {I}_{0} ) q Δ {f ( \frac{2 KT}{{qI}_{0}} {e}^{- \frac{{V}_{D}}{( \frac{KT}{q} )}} )}^{2} + \\ ( 2 α {I}_{S} + {I}_{0} ) q Δ {f ( \frac{2 KT}{{qI}_{0}} {e}^{- \frac{{V}_{D}}{( \frac{KT}{q} )}} )}^{2} + … + \\ ( 2 α {I}_{S} + {I}_{0} ) q Δ {f ( \frac{2 KT}{{qI}_{0}} {e}^{- \frac{{V}_{D}}{( \frac{KT}{q} )}} )}^{2}\end{matrix}}}{p ( \frac{2 KT}{{I}_{0}} {e}^{- \frac{{V}_{D}}{( \frac{KT}{q} )}} )} = \frac{\sqrt{( 2 α {I}_{S} + {I}_{0} ) q Δ f}}{\sqrt{p}} \qquad Eq . 22$$

And the total resistance is

$$p ( \frac{2 KT}{{I}_{0}} {e}^{- \frac{{V}_{D}}{( \frac{KT}{q} )}} ) -$$

this does not gives any thermal noise it is just the slope of the diode current, having C1.

The same is applies to the second diode network 7013.

The total current noise is the square sum of the first diode branch current noise the second diode branch current noise and the gate leakage noise 5014a and is given by:

$${i}_{n , diodes + jfet}^{2} = \frac{( 2 α {I}_{S} + {I}_{0} ) q Δ f}{p} + \frac{( 2 ( 1 - α ) {I}_{S} + {I}_{0} ) q Δ f}{p} + 2 {I}_{S} q Δ f == \frac{( 2 {I}_{S} + 2 {I}_{0} ) q Δ f}{p} + 2 {I}_{S} q Δ f \approx 2 {I}_{S} q Δ f \\ for p \geq 10 \qquad Eq . 23$$

We can conclude that Eq. 15 now will take the form

$${v}_{n , in}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} d f == 2 {I}_{S} q ( \frac{1}{4 {{π}^{2} ( C + {C}_{1} )}^{2}} ) {ξ}_{1} + \frac{8}{3 G} {{KTR}_{{D}^{ξ} 2} [ \frac{( C + {C}_{1} )}{C} ]}^{2} ++ {\frac{4 {KTR}_{{D}^{ξ} 2}}{{G}^{2}} [ \frac{( C + {C}_{1} )}{C} ]}^{2} \qquad Eq . 24$$

One can see from Eq. 24, that C1 helps with reducing the current noise from the PN junction of the JFET and the diode noise, also connecting serial diodes helps with reducing the diode current noise, in effect the noise from the JFET current at the output 5007a and the noise from RD at the output 5010a is reflected to the input by a factor greater than 1

$${[ \frac{( C + {C}_{1} )}{C} ]}^{2}$$

for 1 pa leakage current we had

$${I}_{S} = 1 pa -> 20 {log}_{10} ( \frac{12.6 mv / \sqrt{2}}{0.46 uv} ) = 85 dB .$$

It is possible to increase this term by 10 dB by adding C1=2C, this requires that G will compensate the

$${[ \frac{( C + {C}_{1} )}{C} ]}^{2}$$

so this requires that G=10, still having Rd=100 ohm, this requires gm=0.1, or Id=100 ma, this is possible when using JFET with IDSS=100 ma

Distortion Analysis

The equation of a diode is given by Eq. 21:

$${I}_{D} = {I}_{0} ( {e}^{\frac{{V}_{D}}{( \frac{KT}{q} )}} - 1 ) = {I}_{0} ( ( \frac{{V}_{D}}{{V}_{T}} ) + \frac{1}{2 !} {( \frac{{V}_{D}}{{V}_{T}} )}^{2} + \frac{1}{3 !} {( \frac{{V}_{D}}{{V}_{T}} )}^{3} + \frac{1}{4 !} {( \frac{{V}_{D}}{{V}_{T}} )}^{4} … ) == {I}_{0} ( ( x ) + \frac{1}{2 !} {( x )}^{2} + \frac{1}{3 !} {( x )}^{3} + \frac{1}{4 !} {( x )}^{4} … ) \\ where {V}_{T} = \frac{KT}{q} and x = \frac{{V}_{D}}{{V}_{T}} \qquad Eq . 25$$

It is important to mention that at DC the first diode branch 7003 will force a positive voltage across the diode branch, this will appear to the second diode branch 7013 as negative voltage, to find this voltage one can write:

$${I}_{s} = {I}_{0} ( {e}^{\frac{{V}_{D}}{( \frac{KT}{q} )}} - 1 ) - {I}_{0} ( {e}^{- \frac{{V}_{D}}{( \frac{KT}{q} )}} - 1 ) \qquad Eq . 26$$

mark

$$x = {e}^{\frac{{V}_{D}}{( \frac{KT}{q} )}} solve \frac{{I}_{s}}{{I}_{0}} = x - 1 - \frac{1}{x} + 1 if \frac{{I}_{s}}{{I}_{0}} = 1$$

meaning diode will have leakage in the same order as JFET, this will result at 25 degrees with x=1.618 and v_{D}=12 mv.

As each diode in the first branch 7003 gets V/p and on the second branch 7013 gets −V/p and the current for both branches is the subtraction of the current. while V is the input voltage which is divided over the N branch of diodes, and the reason of +V/p and −V/p is the diode, which are opposite to each other.

The diode on the first branch 7003 may have 12 mV+V/p, and on the diode on the second branch may have −12 mV−V/p, where the 12 mV is due to leakage from the transistor, which flows into Da(1) 7003 branch from the gate of transistor Q 7005. This leakage, which is about 0.1 pA-10 pA, may induce 12 mV on each diode in the branch 7003.

The difference between the branches 7003, 7013 current then:

$${I}_{on \_ diode \_ branches \_ 7003 \_ 7013} = {I}_{0} ( ( x ) + \frac{1}{2 !} {( x )}^{2} + \frac{1}{3 !} {( x )}^{3} + \frac{1}{4 !} {( x )}^{4} … ) - {I}_{0} ( ( - x ) + \frac{1}{2 !} {( x )}^{2} + \frac{1}{3 !} {( x )}^{3} + \frac{1}{4 !} {( x )}^{4} … ) = 2 {I}_{0} ( ( \frac{V / p}{{V}_{T}} ) + \frac{1}{3 !} {( \frac{12 mv}{{V}_{T}} )}^{3} ( 1 + 3 {( \frac{V / p}{12 mv} )}^{2} + 3 ( \frac{V / p}{12 mv} ) + {( \frac{V / p}{12 mv} )}^{3} ) … ) \\ where {V}_{T} = \frac{KT}{q} and x = \frac{V / p + 12 mv}{{V}_{T}} = 2 {I}_{0} ( ( x ) + \frac{1}{3 !} {( x )}^{3} … ) \qquad Eq . 27$$

If we have C=10 pF 7002a at even low frequencies like 100 Hz, It is clear that for 1 pa-10 pA the impedance of a diode is about 25 mV/(2*1e−12)=12.5 gOhm, which means that all Vin will be developed on the input.

The distortion voltage at the input would come from the voltage drop on C and from the distortion elements described by Eq. 27.

For Very small V/p (Assuming microphone acoustic element is about its sensitivity which is about 12 mV this means that 12 mV/10=1.2 mV).

The term

$$3 {( \frac{V / p}{12 mv} )}^{2} \frac{1}{3 !} {( \frac{12 mv}{{V}_{T}} )}^{3} = 2 {I}_{0} \frac{1}{2} {( \frac{V / p}{1} )}^{2} ( \frac{12 mv}{{V}_{T}} ) \approx {{I}_{S} ( \frac{V / p}{1} )}^{2} ( \frac{12 mv}{{V}_{T}} )$$

generates the distortion.

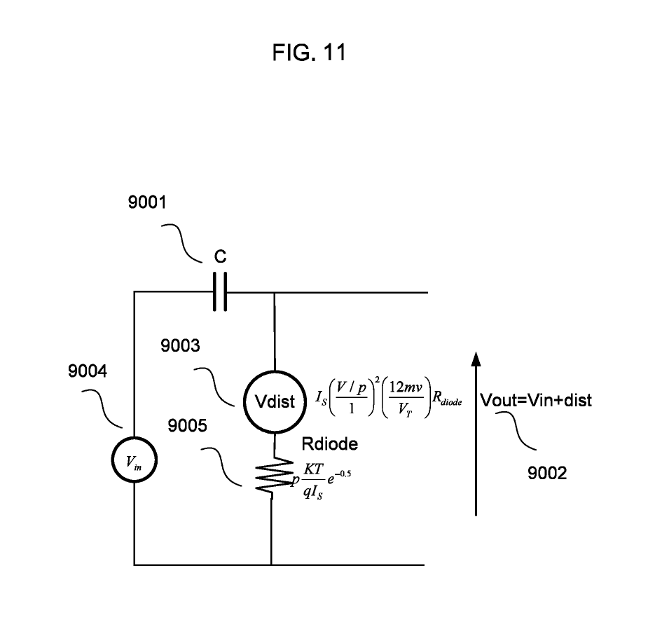

FIG. 11 is a simplified illustration of the distortion due to the diodes network, according to one exemplary embodiment.

$${{I}_{S} ( \frac{{V}_{i n} / p}{1} )}^{2} ( \frac{12 mv}{{V}_{T}} ) ( \frac{1}{jwc} ) \qquad Eq . 28$$

and therefore in dB we have:

$$Distotion [ dB ] = 20 log 10 [ \frac{{{I}_{S} ( \frac{{V}_{i n} / p}{1} )}^{2} ( \frac{12 mv}{{V}_{T}} ) ( \frac{1}{wc} )}{{V}_{i n}} ] \qquad Eq . 29$$

Eq. 29 shows that putting series of diodes will decrease the distortion. For 2 pA current and 10 pF and p=1 and Vin=12 mV, f=100 (at sensitivity level) we have distortion of 23 nV, in audio this might be acceptable, but this means that having a tone at 100.

Distortion Source

Basically for low Is leakage 1 pa-10 pa with one diode the impedance of the diode will be 2500 Mohm-25 Gohm (with 10 pa) at 100 Hz and 10 pf for C 7002a, we have the impedance of 100 Mohm this will give a voltage of 1/25 from the input and for one diode this would mean that for maximal sensitivity the distortion would be 1/25*⅛ which is pretty high with a series p diodes and parallel branches 7003 and 7013 we have for maximal sensitivity—assuming p=10— 1/25*⅙*(1.2/25).̂3=1/1.3M which reflects Distortion of more than 120 dB.

Reason for Series of Diodes

There are two reasons for putting series of diodes in each branch 7003 and 7013: The first due to Eq. 22, this connection reduces the current noise from the diode current noise. The second is to divide the voltage across each diode such that the term (V/p)/25 mv will be small enough.

Reason for Parallel Branches

Parallel branches eliminate the even distortion components—see Eq. 26.

Ultra-Low-Power Low Noise Microphone Circuit

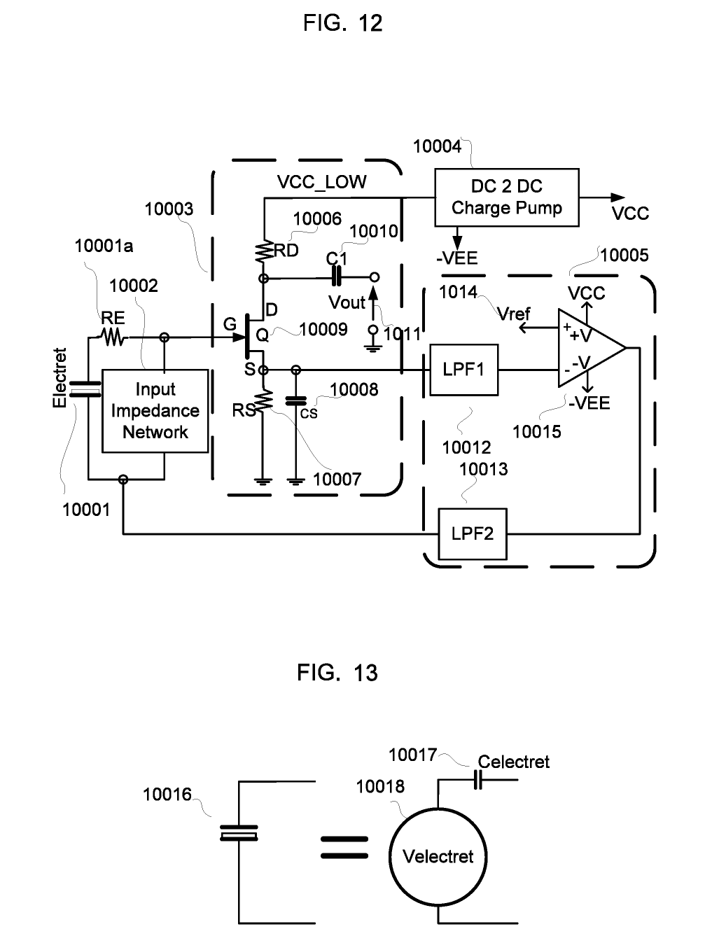

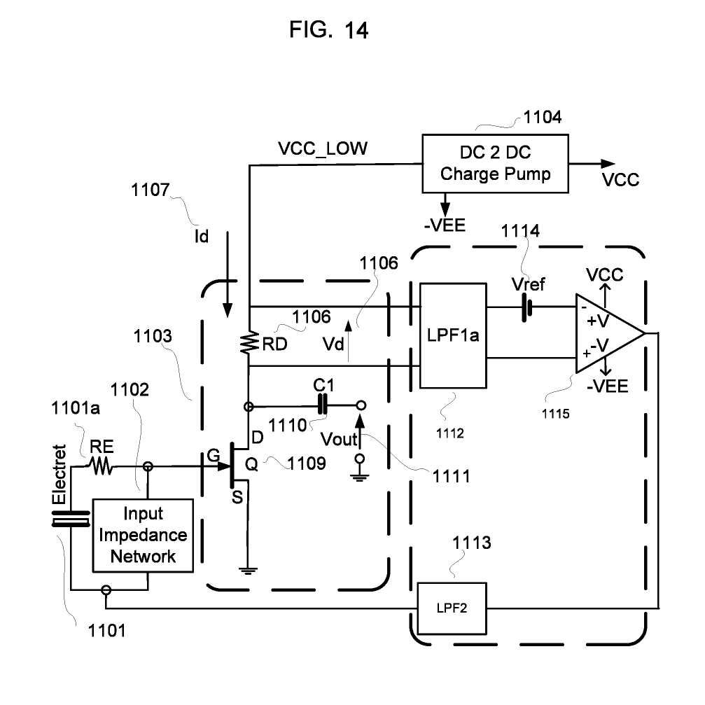

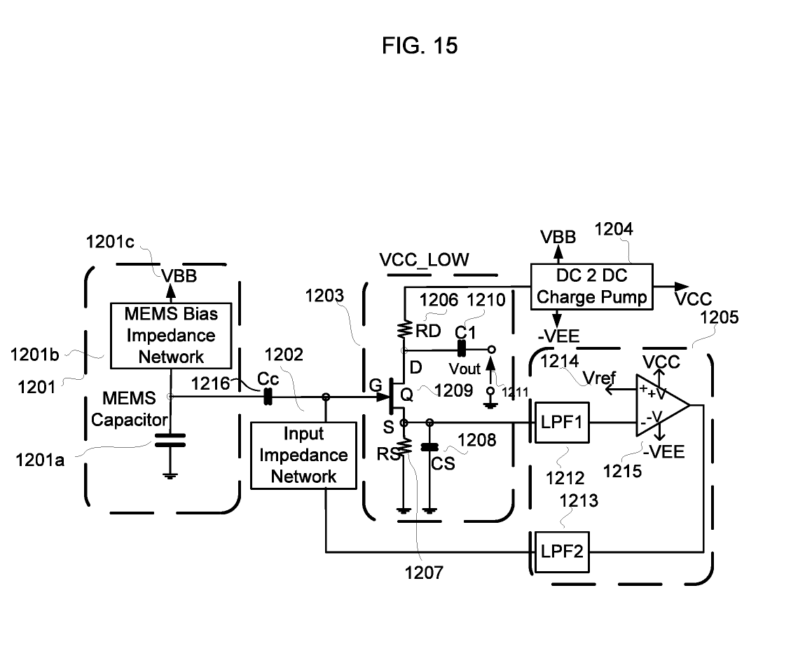

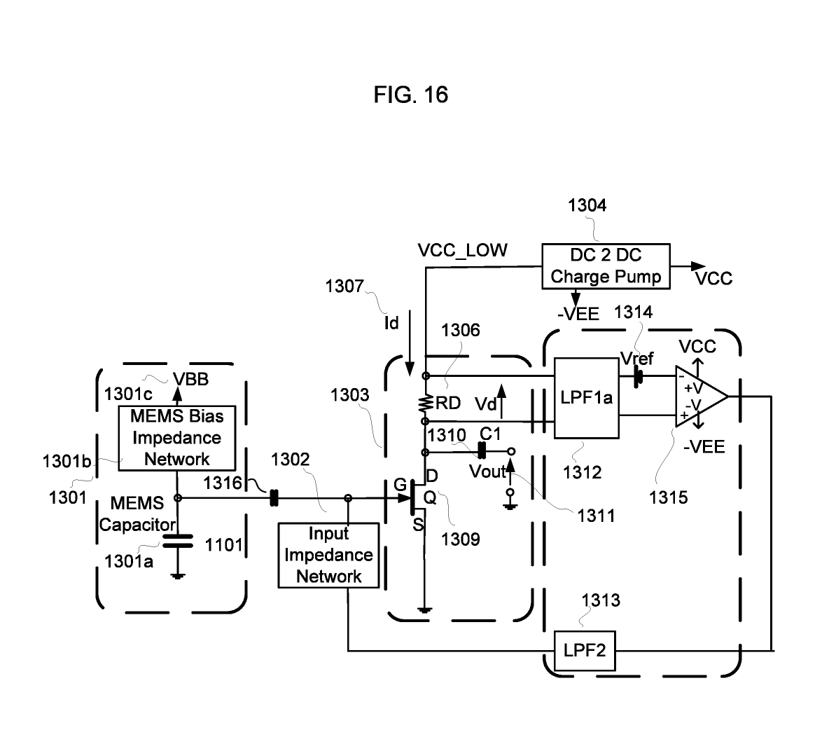

FIG. 12, FIG. 14, FIG. 15, and FIG. 16 describe four alternative circuits for an ultra-low-noise and ultra-low-power microphone.

FIG. 12 is a simplified illustration of an Electret Condenser Microphone (ECM) ultra-low-noise ultra-low-power microphone with feedback from source, according to one exemplary embodiment.

FIG. 13 is a simplified illustration of an Electret equivalent circuit, according to one exemplary embodiment.

FIG. 14 is a simplified illustration of an Electret Condenser Microphone (ECM) ultra-low-noise ultra-low-power microphone with feedback from drain, according to one exemplary embodiment.

FIG. 15 is a simplified illustration of a Micro Electrical Mechanical System Microphone ultra-low-noise ultra-low-power microphone with feedback from source, according to one exemplary embodiment.

FIG. 16 is a simplified illustration of a Micro Electrical Mechanical System Microphone ultra-low-noise ultra-low-power microphone with feedback from drain, according to one exemplary embodiment.

Reference is now made to FIG. 12 and FIG. 13 that describe an ultra-low-power ultra-low-noise microphone. The low noise part is achieved by using a diode-based input impedance 10002, as shown and described with reference to FIG. 5, FIG. 6, FIGS. 7 and 8.

The input impedance may include a parallel capacitor C1 described as 5011, 6011, 7011 and 8011 in FIG. 5, FIG. 6, FIGS. 7 and 8 respectively.

To get the low power performance a wide JFET transistors is used in which the IDSS current is large. Eq. 30 describes the relation between V_{GS} and I_{D} of the JFET 10009, of FIG. 12.

$${I}_{D} = {{I}_{DSS} ( 1 - \frac{{V}_{GS}}{{V}_{P}} )}^{2} ⇒ {g}_{m} = - \frac{2}{{V}_{P}} \sqrt{{I}_{D} {I}_{DSS}} \qquad Eq . 30$$

Recall from equation 24 given here as Eq. 31

$${v}_{n , i n}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} df == 2 {I}_{s} q ( \frac{1}{4 {{π}^{2} ( C + {C}_{1} )}^{2}} ) {ξ}_{1} + \frac{8}{3 G} {KTR}_{D} {{ξ}_{2} [ \frac{( C + {C}_{1} )}{C} ]}^{2} + {\frac{4 {KTR}_{D} {ξ}_{2}}{{G}^{2}} [ \frac{( C + {C}_{1} )}{C} ]}^{2} \qquad Eq . 31$$

The reflected noise at the input may include three elements:

The first noise element

$$- 2 {I}_{S} q ( \frac{1}{4 {{π}^{2} ( C + {C}_{1} )}^{2}} ) {ξ}_{1}$$

is from the PN junction of the JFET 1009 combined with the current noise of the input impedance leakage current diodes 10002.

The second noise element

$$- \frac{8}{3 G} {KTR}_{D} {{ξ}_{2} [ \frac{( C + {C}_{1} )}{C} ]}^{2}$$

comes from the JFET 10009 current noise between drain (D) to source (S).

The third noise element

$$- \frac{4 {KTR}_{D} {ξ}_{2}}{G} [ \frac{( C + {C}_{1} )}{C} ]$$

comes from the RD, load resistor 10006.

The first noise element may be decreased using C1 5011, 6011, 7011 and 8011 in the input impedance and also could be reduced by using JFET with ultra-low leakage Is. The second and third noise elements may be decreased when the gain G is increased. For JFET 10009 in the saturation region we have—

G=gₘR_{D} Eq. 32

Therefore the second and third elements of noise become

$$\begin{matrix}\frac{8}{3 G} {KTR}_{D} {{ξ}_{2} [ \frac{( C + {C}_{1} )}{C} ]}^{2} = \frac{8}{3 {g}_{m}} KT {{ξ}_{2} [ \frac{( C + {C}_{1} )}{C} ]}^{2} & Eq . 33 \\ {\frac{4 {KTR}_{D} {ξ}_{2}}{{G}^{2}} [ \frac{( C + {C}_{1} )}{C} ]}^{2} = {\frac{4 KT}{{g}_{m}^{2} {R}_{D}} [ \frac{( C + {C}_{1} )}{C} ]}^{2} & Eq . 34\end{matrix}$$

One can see from Eq. 33 and Eq. 34 that the second and third reflected input noise depend on gm, so we might want to have a large gm, one can use a wide JFET 1009, such that IDSS is extremely high, such that in order to get some gm,

$$\frac{2}{{V}_{P}} \sqrt{{I}_{D} {I}_{DSS}}$$

we will need to use low Id, for example with prior art microphones a JFET transistor with Vp=1V and IDSS=0.5 ma with VGS=0 is normally used, one can use a IDSS=150 ma to 300 ma JFET with low leakage such as MX-16 of MOXTEK with VP=−8v, with such transistor in order to get the same prior art gm we need a Id=500 ua/300=1.7 ua, in order to have the JFET in saturation region we need V_{DS}≥V_{GS}=V_{P} with such Id we have

$${V}_{GS} - {V}_{P} = \vert {V}_{P} \vert \sqrt{\frac{{I}_{D}}{{I}_{DSS}}} = \frac{\vert {V}_{P} \vert}{300} = \frac{8}{300} = 27 mv \qquad Eq . 35$$

with 1.7 ua,

We also assume about 20 mv for RS 10007 and RD 10006 (10 mv each) this would mean 92 nwatts of power consumption.

The circuit of FIG. 12 includes a DC to DC—switched capacitors voltage converter (charge pump) 1004 that gets a supply voltage VCC and generates VCC_LOW which is the voltage that drives the microphone buffer 10003, this voltage as suggested is about 20 mv-50 mv, with low total power consumption.

Voltage buffer 1003, is comprised of an active element JFET 10009—that could be also implemented using Metal Oxide Semiconductor FET (MOSFET), the buffer 10003 includes a load resistor RD 1005 which is used for amplification, Vout 1011 is taken via coupling capacitor C1 1010.

To set the required Id—that insures with the VCC_LOW that JFET 10009 is in saturation mode, a current control block 1005 is added, this current control block is comprised of un ultra-low-power comparator 1015 and two Low-Pass-Filters 10012 and 10013, the filters are needed to block the noise coming from the ultra-low-power comparator—the comparator which works with a few nano Ampere—would have to work in a very low Gain Bandwidth but would have high noise at its input (a few micro Volts) and high noise at it output, LPF1 is a bi-directional low pass filter that would block the noise coming from the “−” input of the ultra-low-power comparator 10015 on one hand and on the other hand would allow to get a sampled voltage from the RS 1007, which transform the Id into Id*RS this voltage is compared with Vref 10014 and when the feedback is table Vref=Id*RS hence Id=Vref/RS, if Id*Rd>Vref the comparator would generate a negative voltage that is supplied to the gate of the JFET 1009 through LPF2 and the input impedance network 1002, this negative voltage would decrease the current.

The input impedance network 10002 is comprised of a diodes network as described by FIG. 5 5003, FIG. 6 6003, FIG. 7 7003 or FIG. 8 8003, as a very low current Is 5015, 6015, 7015 and 8015 is flowing through the diode network and the leakage Is 5015, 6015, 7015 and 8015 is the same order of the diode leakage, this would mean that each diode would have about KT/q voltage or about 25 mv during DC.

In order to have high gain a bypass capacitor CS 1008 is added in parallel to RS 1007. The charge pump 10014 supplies two voltages VCC_LOW to drive the microphone buffer 1003 and −VEE for the ultra-low-power comparator 1015, the electret element 10001, which is a capacitor with a polarized element would have high voltage on its pins—this voltage is discharged using the diode networks, an optional low resistor (100 ohm) RE 1001a could be added to allow a controlled discharge of the electrets element 10001 during manufacturing, this would limit the discharge current such that the diodes in the diode network 1002 would not be harmed, a parallel capacitor to the input impedance 10002 C1 such as 5011, 6011, 7011 and 8011 could be added in the input impedance, this C1 allows reduction of the noise due to the leakage current from the gate of the JFET 10009.

FIG. 13 describes the model of the electrets 10016, which could be thought as Celectret 10017 in series to Velectret 10018.

Reference is now made to FIG. 13

FIG. 13 is an improved version of the ultra-low-power ultra-low-noise microphone of FIG. 11.

The circuit of FIG. 13 is similar to the one of FIG. 11, except for the feedback part. In circuit of FIG. 13 there is no need for RS 10007 resistor and CS 10008 capacitor, instead the current to voltage is taken from RD the load resistor 1106, through LPF1a 1112, the purpose of LPF1a is to pass the voltage Id*RD to the comparator then −Vref 1114 is added giving a voltage of Id*RD−Vref between the “−” and “+” terminals of the comparator 1115 if of Id*RD−Vref<0 a positive voltage is created at the output of the comparator 1115 which increase the current Id 1107.

The advantage of the circuit of FIG. 13 is the reduction of the VCC_LOW by about the voltage on RS 10007, this will decrease the VCC_LOW and hence would create a microphone buffer 1103 with a lower power consumption.

FIG. 15 describes a similar microphone buffer to the one of FIG. 13, for the use in Micro Electronic Mechanical System (MEMS) microphone, the circuit is similar to the one of FIG. 13, except for the electret element 1001. The electret element 1001 is replaced by a MEMS unit 1201 comprised of a MEMS bias impedance network 1201b and a MEMS capacitor 1201a which translate the acoustic wave pressure into variation in capacitance these variations with the assumption of constant charge on the MEMS capacitor would be translated into voltage variations as

$${V}_{BB} {C}_{electret} = ( {V}_{BB} + Δ V ) ( {C}_{electret} + Δ C ) ⇒ Δ V = - {V}_{BB} \frac{Δ C}{{C}_{electret}}$$

The voltage variations are coupled to the microphone buffer 1203 through Cc c-coupling capacitor 1216.

VBB is the bias voltage for the MEMS capacitor, this voltage could be positive or negative and is generated using the switch capacitor charge pump 1204, in order to generate “clean” VBB sometimes it is required to generate a higher voltage and to pass it through Low Pass Filter and a buffer—which is normally implemented using op amplifier, the op amplifier output is further filtered with high resistors and capacitors.

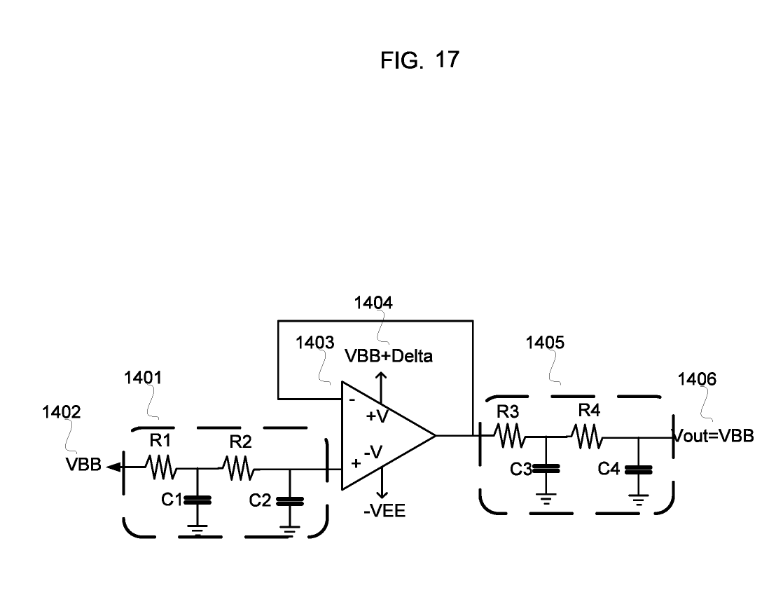

FIG. 17 is a simplified electric schematic of an ultra-low-noise VBB biasing circuit, according to one exemplary embodiment.

The low-noise VBB biasing circuit of FIG. 17 first blocks the noise from the VBB 1402 using LPF 1401, and pass the voltage using a unity gain amplifier 1403. The output of this amplifier, which is assumed to be low power, may have some noise that may be further blocked by a second LPF 1405. The cleaned VBB is then provided at the output 1406.

The MEMS bias impedance network 1201b is a diode network as described in FIG. 5, FIG. 6, FIG. 7 and FIGS. 8 5013, 6013, 7013 and 8013.

It is appreciated that certain features, which are, for clarity, described in the context of separate embodiments, may also be provided in combination in a single embodiment. Conversely, various features, which are, for brevity, described in the context of a single embodiment, may also be provided separately or in any suitable sub-combination.

Although descriptions have been provided above in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art.

1. A microphone comprising:
a transistor comprising at least one of a JFET transistor and a MOSFET transistor;
an input-impedance-network comprising a first terminal connected to a gate terminal of said transistor;
a source resistor comprising a first terminal connected to a source terminal of said transistor, and a second terminal connected to a ground terminal;
a bypass capacitor (CS) connected in parallel to said source resistor;
a load resistor (RD) comprising a first terminal connected to a drain terminal of said transistor;
a charge-pump generating:
a low-voltage (VCC_LOW) connected to said second terminal of said load resistor; and
an inverted voltage (−VEE) connected to a first power supply node of an op amplifier;
said op-amplifier comprising:
a first input terminal connected to said source terminal of said transistor through a bi-directional low-pass-filter;
a second input terminal connected to a reference voltage Vref;
a first power supply terminal connected to said inverted voltage;
a second power supply terminal connected to main supply voltage, and
an output terminal connected to a second terminal of said input-impedance-network through a second low pass filter; and
an electret capacitor connected in parallel to said input-impedance-network.

2. A microphone comprising:
a transistor comprising at least one of a JFET transistor and a MOSFET transistor;
an input-impedance-network comprising a first terminal connected to a gate of said transistor;
a source resistor comprising a first terminal connected to a source terminal of said transistor, and a second terminal connected to a ground terminal;
a bypass capacitor (CS) connected in parallel to said source resistor;
a load resistor (RD) comprising a first terminal connected to a drain terminal of said transistor;
a charge pump generating:
a low voltage power supply VCC_LOW connected to a second terminal of said load resistor; and
an inverted voltage −VEE connected to a first power supply terminal of an op-amplifier; and
said op-amplifier comprising:
a first input terminal connected to the source terminal of said transistor through a bi-directional low-pass-filter;
a second input terminal connected to a reference voltage Vref;
a first power supply terminal connected to said inverted voltage;
a second power supply terminal connected to main supply voltage; and
an output terminal connected to a second terminal of said input-impedance-network through a second low pass filter; and
an input source comprising:
a MEMS capacitor comprising a first terminal connected to ground, and a second terminal connected to a first terminal of a MEMS bias network;
a MEMS bias network comprising a second terminal connected to a bias voltage (VBB); and
a coupling capacitor comprising a first terminal connected to a second terminal of said MEMS capacitor, a second terminal connected to said gate terminal of said transistor.

3. A microphone comprising:
a transistor comprising at least one of a JFET transistor and a MOSFET transistor;
an input-impedance-network comprising a first terminal connected to a gate terminal of said transistor:
a source resistor connected with its first terminal to the source terminal of said transistor and its second terminal to the ground terminal;
a bypass capacitor (CS) connected in parallel to said source resistor;
a load resistor (RD) comprising a first terminal connected to a drain terminal of said transistor;
a charge pump generating:
a low voltage power supply (VCC_LOW) connected to a second terminal of said load resistor; and
an inverted voltage (−VEE) connected to a first power supply terminal of an op amplifier;
said op amplifier comprising
a first input terminal connected to a reference voltage;
a second input terminal connected to said load resistor through a differential bi-directional low-pass-filter;
a first power supply terminal connected to said inverted voltage;
a second supply terminal connected to main supply voltage; and
an output terminal connected to a second terminal of said input impedance network through a second low pass filter; and
an input electrets capacitor source connected in parallel to said input-impedance-network.

4. A microphone comprising:
a transistor comprising at least one of a JFET transistor and a MOSFET transistor;
an input-impedance-network comprising a first terminal connected to a gate terminal of said transistor:
a source resistor connected with its first terminal to the source terminal of said transistor and its second terminal to the ground terminal;
a bypass capacitor (CS) connected in parallel to said source resistor;
a load resistor (RD) comprising a first terminal connected to a drain terminal of said transistor;
a charge pump generating:
a low voltage power supply (VCC_LOW) connected to a second terminal of said load resistor; and
an inverted voltage (−VEE) connected to a first power supply terminal of an op amplifier;
said op amplifier comprising:
a first input terminal connected to a reference voltage connected is series to a first output terminal of a differential bi-directional low-pass-filter, and a second input terminal connected to a second output terminal of said differential bi-directional low-pass-filter, wherein input terminals of said differential bi-directional low-pass-filter are connected in parallel to said load resistor;
a first power supply terminal connected to said inverted voltage;
a second power supply terminal connected to main supply voltage; and
an output terminal connected to a second terminal of said input-impedance-network through a second low-pass-filter; and
an input source comprising:
a MEMS capacitor comprising a first terminal connected to ground, and a second terminal connected to a first terminal of MEMS-bias-network;
a MEMS-bias-network comprising a second terminal connected to a bias voltage (VBB); and
a coupling capacitor comprising a first terminal connected to said second terminal of said MEMS capacitor and a second terminal connected to said gate terminal of said transistor.

5. The microphone according to claim 1, wherein the input-impedance-network comprises a plurality of low-leakage diodes connected in series, wherein:
a cathode of a first diode is the first terminal of the input-impedance-network;
an anode of the first diode is connected to a cathode of a second diode; and
an anode of a last diode is the second terminal of the input impedance network.

6. The microphone according to claim 1, wherein the input-impedance-network comprises a plurality of low-leakage diodes connected in series, wherein:
an anode of a first diode is the first terminal of the input impedance network;
a cathode of the first diode is connected to an anode of a second diode; and
a cathode of a last diode is the second terminal of the input-impedance-network.

7. The microphone according to claim 1, wherein the input-impedance-network comprises a parallel diode network comprising:
a first diode network comprising:
a cathode of a first diode is the first terminal of the input-impedance-network;
an anode of the first diode connected to a cathode of a second diode; and
an anode of the last diode is the second terminal of the input-impedance-network; and
a second diode network comprising:
an anode of a first diode connected to the first terminal of the input-impedance-network;
a cathode of the first diode connected to an anode of a second diode; and
a cathode a last diode connected to the second terminal of the input impedance network.

8. The microphone according to claim 1, wherein the input impedance network comprises a plurality of sub-networks connected in series, and wherein:
a first terminal of a first sub-network is the first terminal of the input-impedance-network,
a second terminal of the first sub-network is connected to a first terminal of a next sub-network; and
a second terminal of a last sub-network is the second terminal of the input-impedance-network;
wherein a sub-network comprises a two identical low-leakage diodes connected in parallel in opposite polarity.

9. The microphone according to claim 1 wherein the MEMS-bias-network comprises a series of low-leakage diodes comprising:
a cathode of a first diode is the first terminal of the MEMS-bias-network;
an anode of the first diode is connected to a cathode of a second diode; and
an anode of a last diode is the second terminal of the MEMS-bias-network.

10. The microphone according to claim 2, wherein the MEMS-bias-network comprises a series of low-leakage diodes comprising:
an anode of a first diode is the first terminal of the MEMS-bias-network;
a cathode of the first diode is connected to an anode of a second diode; and
a cathode of a last diode is the second terminal of the MEMS-bias-network.

11. The microphone according to claim 2, wherein the MEMS-bias-network comprises a parallel diode network comprising:
a first diode network comprising:
a cathode of a first diode is the first terminal of the MEMS-bias-network;
an anode of the first diode connected to a cathode of a second diode; and
an anode of the last diode is the second terminal of the MEMS-bias-network; and
a second diode network comprising:
an anode of a first diode connected to the first terminal of the MEMS-bias-network;
a cathode of the first diode connected to an anode of a second diode; and
a cathode a last diode connected to the second terminal of the MEMS-bias-network.

12. The microphone according to claim 2, wherein the MEMS-bias-network comprises a plurality of sub-networks connected in series, wherein:
a first terminal of a first sub-network is the first terminal of the MEMS-bias-network,
a second terminal of the first sub-network is connected to a first terminal of a next sub-network; and
a second terminal of a last sub-network is the second terminal of MEMS-bias-network;
wherein each sub-network comprises a two identical low-leakage diodes connected in parallel in opposite polarity.

13. A method for sensing an acoustic signal, the method comprising:
connecting an input-impedance-network comprising a first terminal to a gate terminal of a transistor comprising at least one of a JFET transistor and a MOSFET transistor;
connecting a first terminal of a source resistor to a source terminal of said transistor, and a second terminal of said source resistor to a ground terminal;
connecting a bypass capacitor (CS) in parallel to said source resistor;
connecting a first terminal of a load resistor (RD) to a drain terminal of said transistor;
connecting a low-voltage (VCC_LOW) generated by a charge-pump to said second terminal of said load resistor; and
connecting an inverted voltage (−VEE) generated by said charge-pump to a first power supply node of an op amplifier;
connecting a first input terminal of said op-amplifier to said source terminal of said transistor through a bi-directional low-pass-filter;
connecting a second input terminal of said op-amplifier to a reference voltage Vref;
connecting a first power supply terminal of said op-amplifier to said inverted voltage;
connecting a second power supply terminal of said op-amplifier to main supply voltage,
connecting an output terminal of said op-amplifier to a second terminal of said input-impedance-network through a second low pass filter; and
connecting an electret capacitor in parallel to said input-impedance-network.

14. A method for sensing an acoustic signal, the method comprising:
connecting an input-impedance-network comprising a first terminal to a gate terminal of a transistor comprising at least one of a JFET transistor and a MOSFET transistor;
connecting a first terminal of a source resistor to a source terminal of said transistor, and a second terminal of said source resistor to a ground terminal;
connecting a bypass capacitor (CS) in parallel to said source resistor;
connecting a first terminal of a load resistor (RD) to a drain terminal of said transistor;
connecting a low-voltage (VCC_LOW) generated by a charge-pump to said second terminal of said load resistor; and
connecting an inverted voltage (−VEE) generated by said charge-pump to a first power supply node of an op amplifier;
connecting a first input terminal of said op-amplifier to said source terminal of said transistor through a bi-directional low-pass-filter;
connecting a second input terminal of said op-amplifier to a reference voltage Vref;
connecting a first power supply terminal of said op-amplifier to said inverted voltage;
connecting a second power supply terminal of said op-amplifier to main supply voltage,
connecting an output terminal of said op-amplifier to a second terminal of said input-impedance-network through a second low pass filter; and
connecting an input source comprising:
a MEMS capacitor comprising a first terminal connected to ground, and a second terminal connected to a first terminal of a MEMS bias network;
a MEMS bias network comprising a second terminal connected to a bias voltage (VBB); and
a coupling capacitor comprising a first terminal connected to a second terminal of said MEMS capacitor, a second terminal connected to said gate terminal of said transistor.

15. A method for sensing an acoustic signal, the method comprising:
connecting an input-impedance-network comprising a first terminal to a gate terminal of a transistor comprising at least one of a JFET transistor and a MOSFET transistor;
connecting a first terminal of a source resistor to a source terminal of said transistor, and a second terminal of said source resistor to a ground terminal;
connecting a bypass capacitor (CS) in parallel to said source resistor;
connecting a first terminal of a load resistor (RD) to a drain terminal of said transistor;
connecting a low-voltage (VCC_LOW) generated by a charge-pump to said second terminal of said load resistor; and
connecting an inverted voltage (−VEE) generated by said charge-pump to a first power supply node of an op amplifier;
connecting a first input terminal of said op-amplifier to a reference voltage;
connecting a second input terminal of said op-amplifier to said load resistor through a differential bi-directional low-pass-filter;
connecting a first power supply terminal of said op-amplifier to said inverted voltage;
connecting a second power supply terminal of said op-amplifier to main supply voltage,
connecting an output terminal of said op-amplifier to a second terminal of said input-impedance-network through a second low pass filter; and
connecting an input electrets capacitor source in parallel to said input-impedance-network.

16. A method for sensing an acoustic signal, the method comprising:
connecting an input-impedance-network comprising a first terminal to a gate terminal of a transistor comprising at least one of a JFET transistor and a MOSFET transistor;
connecting a first terminal of a source resistor to a source terminal of said transistor, and a second terminal of said source resistor to a ground terminal;
connecting a bypass capacitor (CS) in parallel to said source resistor;
connecting a first terminal of a load resistor (RD) to a drain terminal of said transistor;
connecting a low-voltage (VCC_LOW) generated by a charge-pump to said second terminal of said load resistor; and
connecting an inverted voltage (−VEE) generated by said charge-pump to a first power supply node of an op amplifier;
connecting a first input terminal of said op amplifier to a reference voltage connected is series to a first output terminal of a differential bi-directional low-pass-filter;
connecting a second input terminal to a second output terminal of said differential bi-directional low-pass-filter;
connecting input terminals of said differential bi-directional low-pass-filter in parallel to said load resistor;
connecting a first power supply terminal to said inverted voltage;
connecting a second power supply terminal to main supply voltage
connecting an output terminal to a second terminal of said input-impedance-network through a second low-pass-filter; and
connecting an input source comprising:
a MEMS capacitor comprising a first terminal connected to ground, and a second terminal connected to a first terminal of MEMS-bias-network;
a MEMS-bias-network comprising a second terminal connected to a bias voltage (VBB); and
a coupling capacitor comprising a first terminal connected to said second terminal of said MEMS capacitor and a second terminal connected to said gate terminal of said transistor.

17. The microphone according to claim 4, wherein the MEMS-bias-network comprises a series of low-leakage diodes comprising:
an anode of a first diode is the first terminal of the MEMS-bias-network;
a cathode of the first diode is connected to an anode of a second diode; and
a cathode of a last diode is the second terminal of the MEMS-bias-network.

18. The microphone according to claim 4, wherein the MEMS-bias-network comprises a parallel diode network comprising:
a first diode network comprising:
a cathode of a first diode is the first terminal of the MEMS-bias-network;
an anode of the first diode connected to a cathode of a second diode; and
an anode of the last diode is the second terminal of the MEMS-bias-network; and
a second diode network comprising:
an anode of a first diode connected to the first terminal of the MEMS-bias-network;
a cathode of the first diode connected to an anode of a second diode; and
a cathode a last diode connected to the second terminal of the MEMS-bias-network.

19. The microphone according to claim 4, wherein the MEMS-bias-network comprises a plurality of sub-networks connected in series, wherein:
a first terminal of a first sub-network is the first terminal of the MEMS-bias-network,
a second terminal of the first sub-network is connected to a first terminal of a next sub-network; and
a second terminal of a last sub-network is the second terminal of MEMS-bias-network;
wherein each sub-network comprises a two identical low-leakage diodes connected in parallel in opposite polarity.

20. The microphone according to claim 2, wherein the input-impedance-network comprises a plurality of low-leakage diodes connected in series, wherein:
a cathode of a first diode is the first terminal of the input-impedance-network;
an anode of the first diode is connected to a cathode of a second diode; and
an anode of a last diode is the second terminal of the input impedance network.

21. The microphone according to claim 2, wherein the input-impedance-network comprises a plurality of low-leakage diodes connected in series, wherein:
an anode of a first diode is the first terminal of the input impedance network;
a cathode of the first diode is connected to an anode of a second diode; and
a cathode of a last diode is the second terminal of the input-impedance-network.

22. The microphone according to claim 2, wherein the input-impedance-network comprises a parallel diode network comprising:
a first diode network comprising:
a cathode of a first diode is the first terminal of the input-impedance-network;
an anode of the first diode connected to a cathode of a second diode; and
an anode of the last diode is the second terminal of the input-impedance-network; and
a second diode network comprising:
an anode of a first diode connected to the first terminal of the input-impedance-network;
a cathode of the first diode connected to an anode of a second diode; and
a cathode a last diode connected to the second terminal of the input impedance network.

23. The microphone according to claim 2, wherein the input impedance network comprises a plurality of sub-networks connected in series, and wherein:
a first terminal of a first sub-network is the first terminal of the input-impedance-network,
a second terminal of the first sub-network is connected to a first terminal of a next sub-network; and
a second terminal of a last sub-network is the second terminal of the input-impedance-network;
wherein a sub-network comprises a two identical low-leakage diodes connected in parallel in opposite polarity.

24. The microphone according to claim 2, wherein the MEMS-bias-network comprises a series of low-leakage diodes comprising:
a cathode of a first diode is the first terminal of the MEMS-bias-network;
an anode of the first diode is connected to a cathode of a second diode; and
an anode of a last diode is the second terminal of the MEMS-bias-network.

25. The microphone according to claim 3, wherein the input-impedance-network comprises a plurality of low-leakage diodes connected in series, wherein:
a cathode of a first diode is the first terminal of the input-impedance-network;
an anode of the first diode is connected to a cathode of a second diode; and
an anode of a last diode is the second terminal of the input impedance network.

26. The microphone according to claim 3, wherein the input-impedance-network comprises a plurality of low-leakage diodes connected in series, wherein:
an anode of a first diode is the first terminal of the input impedance network;
a cathode of the first diode is connected to an anode of a second diode; and
a cathode of a last diode is the second terminal of the input-impedance-network.

27. The microphone according to claim 3, wherein the input-impedance-network comprises a parallel diode network comprising:
a first diode network comprising:
a cathode of a first diode is the first terminal of the input-impedance-network;
an anode of the first diode connected to a cathode of a second diode; and
an anode of the last diode is the second terminal of the input-impedance-network; and
a second diode network comprising:
an anode of a first diode connected to the first terminal of the input-impedance-network;
a cathode of the first diode connected to an anode of a second diode; and
a cathode a last diode connected to the second terminal of the input impedance network.

28. The microphone according to claim 3, wherein the input impedance network comprises a plurality of sub-networks connected in series, and wherein:
a first terminal of a first sub-network is the first terminal of the input-impedance-network,
a second terminal of the first sub-network is connected to a first terminal of a next sub-network; and
a second terminal of a last sub-network is the second terminal of the input-impedance-network;
wherein a sub-network comprises a two identical low-leakage diodes connected in parallel in opposite polarity.

29. The microphone according to claim 3, wherein the MEMS-bias-network comprises a series of low-leakage diodes comprising:
a cathode of a first diode is the first terminal of the MEMS-bias-network;
an anode of the first diode is connected to a cathode of a second diode; and
an anode of a last diode is the second terminal of the MEMS-bias-network.

30. The microphone according to claim 4, wherein the input-impedance-network comprises a plurality of low-leakage diodes connected in series, wherein:
a cathode of a first diode is the first terminal of the input-impedance-network;
an anode of the first diode is connected to a cathode of a second diode; and
an anode of a last diode is the second terminal of the input impedance network.

31. The microphone according to claim 4, wherein the input-impedance-network comprises a plurality of low-leakage diodes connected in series, wherein:
an anode of a first diode is the first terminal of the input impedance network;
a cathode of the first diode is connected to an anode of a second diode; and
a cathode of a last diode is the second terminal of the input-impedance-network.

32. The microphone according to claim 4, wherein the input-impedance-network comprises a parallel diode network comprising:
a first diode network comprising:
a cathode of a first diode is the first terminal of the input-impedance-network;
an anode of the first diode connected to a cathode of a second diode; and
an anode of the last diode is the second terminal of the input-impedance-network; and
a second diode network comprising:
an anode of a first diode connected to the first terminal of the input-impedance-network;
a cathode of the first diode connected to an anode of a second diode; and
a cathode a last diode connected to the second terminal of the input impedance network.

33. The microphone according to claim 4, wherein the input impedance network comprises a plurality of sub-networks connected in series, and wherein:
a first terminal of a first sub-network is the first terminal of the input-impedance-network,
a second terminal of the first sub-network is connected to a first terminal of a next sub-network; and
a second terminal of a last sub-network is the second terminal of the input-impedance-network;
wherein a sub-network comprises a two identical low-leakage diodes connected in parallel in opposite polarity.

34. The microphone according to claim 4, wherein the MEMS-bias-network comprises a series of low-leakage diodes comprising:
a cathode of a first diode is the first terminal of the MEMS-bias-network;
an anode of the first diode is connected to a cathode of a second diode; and
an anode of a last diode is the second terminal of the MEMS-bias-network.
